(19) United States
(12) Patent Application Publication
(10) Pub. No.: US 2007/0034159 A1
(43) Pub. Date: Feb. 15, 2007

(54) Semiconductor manufacturing device and its heating unit

(76) Inventors: Mitsuaki Komino, TOKYO (JP); Masato Yonemitsu, Tokyo (JP); Kenji Saito, Tokyo (JP); Miura Kuniaki, Ibaraki (JP); Abe Yuji, Ibaraki (JP); Makoto Asaba, Ibaraki (JP)

Correspondence Address: WENDEROTH, LIND & PONACK, L.L.P., 2033 K STREET N. W., SUITE 800, WASHINGTON, DC, 20006-1021, US

(21) Appl. No.: 10/556,067

(22) PCT Filed: May 19, 2004
(86) PCT No.: PCT/JP04/07114

§ 371 Date: Nov. 8, 2005

(30) Foreign Application Priority Data
May 23, 2005 (JP) 2003-145790
Nov. 28, 2003 (JP) 2003-399372
Dec. 1, 2003 (JP) 2003-401509
Feb. 12, 2004 (JP) 2004-034872

(51) Int. Cl. C23C 16/00; H05B 3/10

(52) U.S. Cl. 118/725; 219/552

(57) ABSTRACT

A semiconductor manufacturing device according to the present invention includes a processing chamber (11), a transferring passage (12) through which a wafer is put in and taken out of the processing chamber (11), an exhaust passage (13) and exhaust lines (40 and 40′) through which a processing gas inside the processing chamber (11) is exhausted, and so on, and in order to heat the inner wall faces (11a, 11b, 12a, 13a, 410a, and 420a) of the processing chamber (11), the transferring passage (12), the exhaust passage (13) and the exhaust pipes (410 and 420), further includes sheet-like heating units (50, 60, 70, 80, 170, and 270) that sandwich and cover a thin plate-shaped resistive heating element by a pair of metal plates and cover the inner wall faces from the inner side. Thereby, the heating efficiency on the wall faces to be exposed to the processing gas increases, adhesion of by-products can be prevented, and deterioration of the resistive heating element can also be prevented.

### TECHNICAL FIELD

The present invention relates to a semiconductor manufacturing device such as a CVD device or etching device, etc., and a heating unit thereof, and more specifically, a semiconductor manufacturing device and a heating unit thereof in that inner wall faces of a processing chamber, a wafer transferring passage, and an exhaust pipe are heated.

### BACKGROUND ART

In a semiconductor manufacturing device such as a CVD device or etching device, etc., a wafer is set inside a processing chamber and subjected to desired deposition and etching while vacuuming in a high-temperature atmosphere. In this process, both vapor phase and solid phase of a processing gas and reaction by-products flowing in the internal space are sublimated and changed, and in particular, when a vapor is changed into a solid, it adheres to the inner wall face as a deposit.

Therefore, in order to evenly apply desired deposition or etching to the wafer while preventing adhesion of unnecessary by-products, etc., to the inner wall face, the wall face temperature of the processing chamber or passage needs to be controlled.

As a conventional method for this, it is known that a cartridge-type heater is disposed together with thermo cement as a heat transfer medium in the outer region of the inner wall face that defines the processing chamber (for example, Japanese Published Unexamined Patent Publication No. 2003-27240).

However, according to the method in which a cartridge-type heater is disposed outside the processing chamber, the heater is locally disposed outside the processing chamber, and the distance from the heater to the wall face of the processing chamber differs depending on the location, so that the inner wall face cannot be evenly heated. In addition, between the heater and the wall face, although a heat transfer medium such as thermo cement is interposed, the heating efficiency is lower than in the case of direct heating, the temperature rising time is long until the temperature reaches a predetermined temperature by heating of the heater, and this results in reduction in the operating time. Furthermore, in actuality, the inner wall face is periodically cleaned to remove by-products adhering to the inner wall face.

In the exhaust pipe or the like joined to the downstream side of the processing chamber, in order to prevent adhesion of by-products or make by-products to locally adhere to the inner wall face inside the duct, a method in which a part of the exhaust pipe is heated from the outside by a heater is known (for example, Japanese Published Unexamined Patent Publications No. 2003-37070 and No. H08-78300).

However, in the method in which a heater is provided outside the exhaust pipe, a part of heat energy is radiated toward the outside of the exhaust pipe, so that the energy efficiency for heating the inner wall face of the exhaust pipe to be contacted by an exhaust gas or the like to a predetermined temperature is poor, and results in an increase in power consumption.

Furthermore, as another method, it is known that a heater is provided in a zigzag manner on the inner wall of the piping of the exhaust pipe, etc., a lead wire of the heater is extracted to the outside from a port provided at the middle portion of the piping, and power is supplied to the heater via this lead wire, whereby the inside of the pipe is heated all around (for example, Japanese Published Unexamined Patent Publication NO. H11-108283).

However, in this method, the port for the lead wire is positioned at the middle of the piping, so that it is difficult to insert the lead wire into the port when the heater is attached, resulting in poor operability.

In addition, since the heater is disposed while being exposed inside the piping, it is worn out due to reaction with a gas or chemical reacting substances that have chemically reacted flowing inside the piping, and in particular, a cleaning gas of NF₃ or ClF₃, etc., that is periodically flowed for removing deposits inside the piping promotes wear of the heater and shortens the life of the heater.

Furthermore, although the heater disposed in a zigzag manner heats all around the piping, only local heating of the vicinity of the heater causes heating temperature unevenness, and by-products are sublimated and easily deposited in a region in that the heat is hardly transmitted.

### DISCLOSURE OF THE INVENTION

The present invention has been made in view of the above-described circumstances, and it is an object of the present invention to minimize adhesion of by-products to the inner wall face of the duct or processing chamber, etc., exposed to a processing gas or the like in a semiconductor manufacturing device or the like, thereby providing a semiconductor manufacturing device and a heating unit thereof which improve the yield of wafers to be processed, increase the operating time, and reduce power consumption by improving the energy efficiency.

The semiconductor manufacturing device according to the present invention to achieve the above-described object includes a processing chamber for applying a predetermined process, a supply passage for supplying a processing gas to the inside of the processing chamber, a transferring passage through which a wafer is put in and taken out of the processing chamber, an exhaust passage for exhausting the processing gas inside the processing chamber, and a sheet-like heating unit formed so as to cover a thin plate-shaped resistive heating element by sandwiching it by a pair of metal plates and cover the inner wall face from the inner side to heat the inner wall face of at least one of the supply passage, the transferring passage, the processing chamber, and the exhaust passage.

According to this construction, by disposing the sheet-like heating unit adjacent to the inner wall face and demarcating a wall face to be exposed to a processing gas, the wall face to be exposed to the processing gas is directly heated, and this improves the heating efficiency and energy efficiency, shortens the heat rising time, reduces power consumption, improves the operating efficiency, and prevents or minimizes adhesion of by-products. In addition, since the resistive heating element of the heating unit is sandwiched and covered by a pair of metal plates, it is prevented from being directly exposed to the processing gas, whereby deterioration and wearing thereof are prevented and predetermined heating performance can be maintained.

Thereby, improvement in the yield of wafers to be processed by the semiconductor manufacturing device, an increase in the operating time, and reduction in power consumption are realized.

In the above-described construction, the heating unit can be constructed so as to include a heating main body to be disposed adjacent to the inner wall face, an attaching portion formed into a flange shape integrally with the heating main body or to extend from the heating main body, and a connector provided at the attaching portion so as to draw-out a wiring for supplying electricity to the resistive heating element and a wiring of a temperature sensor that detects the temperature of the resistive heating element.

According to this construction, when the heating unit is attached to a predetermined heating region (inner wall face), the heating main body is set along the inside of the inner wall face and the attaching portion that is formed into a flange shape or to extend is fixed to a predetermined attaching position, whereby the attaching operation can be easily performed. In addition, since the connector is formed integrally with the attaching portion of the heating unit, it is easily handled and exposed to the outside of the device, whereby an operator is relieved from troublesomeness in connecting in the vacuum atmosphere and can easily connect the wiring after attaching.

In the above-described construction, it is possible that the piping defining the exhaust passage is formed of a plurality of pipes formed to be detachable and joined to each other, and the plurality of pipes have sword guard-shaped flange portions that project outward radially and face each other, and the attaching portion of the heating unit is sandwiched by the flange portions adjacent to each other via a sealing member.

According to this construction, the heating main body of the heating unit is inserted inside the respective pipes and the attaching portion of the heating unit is sandwiched between flange portions of the adjacent pipes via a sealing member and the adjacent pipes are joined to each other, whereby the heating unit can be attached to the piping, and it can be removed by reverse procedures.

In the above-described construction, it is possible that a clamp mechanism for joining the flange portions of the plurality of pipes to each other is provided, and this clamp mechanism includes a plurality of clamp blocks having grooves with roughly V-shaped sections for receiving the flange portions so as to press these closer to each other, a plurality of link plates for linking the plurality of clamp blocks, fastening members that fasten the adjacent two clamp blocks.

According to this construction, since the clamp mechanism is formed into a chain shape, the clamp blocks are wound around the flange portions of the pipes and fastened by the fastening members, whereby the pipes attached with the heating unit can be easily joined to each other and released from each other.

In the above-described construction, it is possible that the plurality of link plates include a plurality of first link plates that link one side portions of the clamp blocks to each other and a plurality of second link plates that links the other side portions of the clamp blocks to each other, wherein at least one link plate of the first link plates and the second link plates can be latched on and released from the clamp blocks.

According to this construction, when a wiring is connected to the attaching portion (or connector) of the heating unit, the wiring is inserted while the releasable link plates are released in advance, and then, the link plates are latched on the clamp blocks, whereby the heating unit can be easily assembled even when the wiring is connected.

The heating unit of the semiconductor manufacturing device of the present invention for achieving the above-mentioned object heats the inner wall face of any of a processing chamber for applying a predetermined process, a transferring passage through which a wafer is put in and taken out of the processing chamber, and an exhaust passage for exhausting a processing gas inside the processing chamber, and includes a thin plate-shaped resistive heating element and a pair of metal plates that covers the resistive heating element by sandwiching it and demarcates the processing chamber or passages so as to cover the inner wall face like a sheet from the inner side.

According to this construction, by disposing the heating unit adjacent to the inner wall face and demarcating the wall face to be exposed to the processing gas, the wall face to be exposed to the processing gas is directly heated, the heating efficiency and energy efficiency are improved, the temperature rising time can be shortened, power consumption can be reduced, the operating efficiency can be improved, and adhesion of by-products can be prevented or minimized. The sheet-like resistive heating element of the heating unit is sandwiched and covered by a pair of metal plates, so that it is prevented from being directly exposed to the processing gas, and deterioration and wearing thereof can be prevented, and predetermined heating performance can be maintained over a long period of time.

In the above-described construction, it is possible that the heating unit includes a heating main body to be disposed adjacent to the inner wall face, an attaching portion formed into a flange shape integrally with the heating main body or formed to extend from the heating main body, and a connector that is provided at the attaching portion to draw-out a wiring for supplying electricity to the resistive heating element and a wiring of a temperature sensor that detects the temperature of the resistive heating element.

According to this construction, when the heating unit is attached to a predetermined heating region (inner wall face), the heating main body is set along the inside of the inner wall face and the attaching portion formed into a flange shape or extended is fixed to a predetermined attaching position, whereby the attaching operation can be easily performed. In addition, the connector is formed integrally with the attaching portion of the heating unit, so that handling is easy and the unit can be exposed to the outside of the device, whereby the operator is relieved from troublesomeness in connecting in the vacuum atmosphere and easily performs wiring connecting operations after attaching.

In the above-described construction, it is possible that the heating unit includes a chamber heating unit to be disposed adjacent to the inner wall face of the processing chamber, and the chamber heating unit includes a cylindrical heating main body to be disposed adjacent to the side wall face of the processing chamber and an attaching portion provided in a flange shape at the end thereof, and a disk-shaped heating main body to be disposed opposite the bottom wall face of the processing chamber and an attaching portion provided to extend on the lower surface of the heating main body.

According to this construction, since the inner wall faces (side wall face and bottom wall face) of the processing chamber are all covered by a sheet-like heating unit, as well as realizing efficient heating and preventing or minimizing adhesion of by-products, when the chamber heating unit is attached, the disk-shaped heating main body is inserted into the processing chamber and the extending attaching portion is made to project from the lower side of the device, and the disk-shaped heating main body is inserted into the processing chamber and the flange-shaped attaching portion thereof is placed on the upper end of the device, so that the heating unit can be easily attached and detached.

In the above-described construction, it is possible that the heating unit includes a chamber heating unit to be disposed adjacent to the inner wall face of the processing chamber and the chamber heating unit includes a cylindrical heating main body having a bottom wall and an attaching portion provided in a flange shape at the opening end of the heating main body.

According to this construction, as well as efficiently heating the inner wall face of the processing chamber and preventing or minimizing adhesion of by-products, when attaching the chamber heating unit, only by inserting the bottomed cylindrical heating main body into the processing chamber and placing the flange-shaped attaching portion on the upper end of the device, all inner wall faces (side wall face and bottom wall face) of the processing chamber are covered with the sheet-like heating unit, so that the heating unit can be easily attached and detached, and by integrally forming the cylindrical heating main body and the disk-shaped heating main body, the number of parts can be reduced.

In the above-described construction, it is possible that the heating unit includes a transferring passage heating unit to be disposed adjacent to the inner wall face of the transferring passage, and the transferring passage heating unit includes a cylindrical heating main body having a roughly rectangular section and an attaching portion provided in a flange shape on the heating main body.

According to this construction, as well as realizing efficient heating of the inner wall face of the transferring passage and preventing or minimizing adhesion of by-products, when attaching the transferring passage heating unit, the cylindrical heating main body is inserted into the transferring passage and the flange-shaped attaching portion is joined to the outer wall face of the device, whereby the heating unit can be easily attached and detached.

In the above-described construction, it is possible that the heating unit includes an exhaust passage heating unit to be disposed adjacent to the inner wall face of the exhaust passage, and the exhaust passage heating unit includes a cylindrical heating main body and an attaching portion provided in a flange shape on the heating main body.

According to this construction, as well as realizing efficient heating of the inner wall face of the exhaust passage and preventing or minimizing adhesion of by-products, when attaching the exhaust passage heating unit, the cylindrical heating main body is inserted into the exhaust passage and the flange-shaped attaching portion is joined to the end of the piping, whereby the unit can be easily attached and detached.

In the above-described construction, it is possible that the heating unit includes an exhaust passage heating unit to be disposed adjacent to the inner wall face of a curved exhaust passage, and the exhaust passage heating unit includes a curved cylindrical heating main body and an attaching portion provided in a flange shape on the heating main body, and the heating main body is formed so as to generate a greater heating value to the outside region of the curved exhaust passage than to the inside region.

According to this construction, at the curved exhaust passage, by-products more easily deposit in the outside region than in the inside region, and the deposit and growth of the by-products in this region can be effectively prevented.

In the above-described construction, it is possible that the heating unit can be disposed by leaving a heat insulating space between it and the inner wall face.

According to this construction, since a vapor phase is formed between the heating unit (heating main body) and the inner wall face, the vapor phase increases the heat insulating effect, whereby the heating efficiency on the wall face to be exposed to the processing gas can be further increased.

In the above-described construction, it is possible that the pair of metal plates are formed of any material of stainless steel, titanium, an aluminum alloy, and a nickel-cobalt alloy, and the resistive heating element is formed of any of a polyimide heater, a silicon rubber heater, a mica heater, and a sheath heater.

According to this construction, the heating unit can be finished into a thin plate shape (sheet shape) that is comparatively easily machined while maintaining high resistance to corrosion and high heat conductivity, so that the heating unit can be easily formed according to the shape of the wall face of the processing chamber and the wall faces of the passages.

### BRIEF DESCRIPTION OF THE DRAWINGS

FIG. 1 is a graph of sublimation curves of reaction by-products;

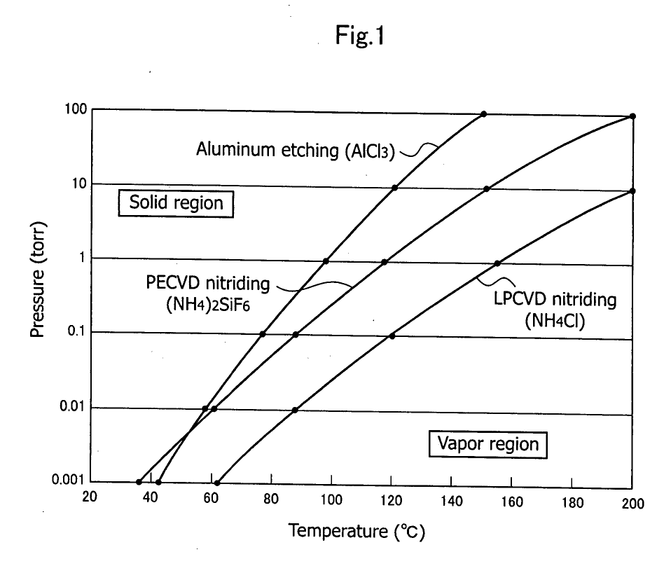

FIG. 2 is an external perspective view showing a semiconductor manufacturing device to which a heating unit according to the present invention is attached;

FIG. 3 is a sectional view of the semiconductor manufacturing device attached with the heating unit of the present invention;

FIG. 4 is an external perspective view of a chamber heating unit according to the present invention;

FIG. 5 is a sectional view of the chamber heating unit shown in FIG. 4;

FIG. 6 is a construction view showing a resistive heating element as a part of the heating unit according to the present invention;

FIG. 7 is an external perspective view of a chamber heating unit according to the present invention;

FIG. 8 is a sectional view of the chamber heating unit shown in FIG. 7;

FIG. 9 is a sectional view showing another embodiment of the chamber heating unit according to the present invention;

FIG. 10 is an external perspective view of an exhaust passage heating unit according to the present invention;

FIG. 11 is a sectional view of the exhaust passage heating unit shown in FIG. 10;

FIG. 12 is an external perspective view of a transferring passage heating unit according to the present invention;

FIG. 13 is a sectional view of the transferring passage heating unit shown in FIG. 12;

FIG. 14 is a sectional view showing another embodiment of the exhaust passage heating unit according to the present invention attached to an exhaust pipe;

FIG. 15 is an enlarged sectional view showing a part of the exhaust passage heating unit shown in FIG. 14 in an enlarged manner;

FIG. 16 is a construction view showing a clamp mechanism that joins exhaust pipes to each other while the exhaust passage heating unit is attached.

FIG. 17 is an external perspective view showing another embodiment of the exhaust passage heating unit according to the present invention;

FIG. 18 is a sectional view of the exhaust passage heating unit shown in FIG. 17;

FIG. 19A is a half sectional view of an outer shell and a flange as a part of the exhaust passage heating unit shown in FIG. 17, and FIG. 19B is a half sectional view of an inner shell and a flange as a part of the exhaust passage heating unit shown in FIG. 17;

FIG. 20A is a graph showing temperature rising characteristics of a heating unit according to the present invention and a conventional rubber heater, and FIG. 20B is a graph showing temperature lowering characteristics of the heating unit according to the present invention and the conventional rubber heater.

FIG. 21 is a sectional view of the exhaust passage heating unit according to the present invention and a graph showing temperature distribution in the axial direction;

FIG. 22 is a sectional view of still another embodiment of the exhaust passage heating unit according to the present invention;

FIG. 23A and FIG. 23B are enlarged sectional views showing a part of an exhaust passage heating unit shown in FIG. 22 in an enlarged manner;

FIG. 24A is a partial half sectional view showing a part of an outer shell forming a part of the exhaust passage heating unit shown in FIG. 22 in an exploded manner, and FIG. 24B is a partial half sectional view showing a part of an inner shell forming a part of the exhaust passage heating unit shown in FIG. 22 in an exploded manner;

FIG. 25 is a developed view of a resistive heating element forming a part of the exhaust passage heating unit shown in FIG. 22;

FIG. 26 is a perspective view showing a three dimensional state of the resistive heating element shown in FIG. 25;

FIG. 27A, FIG. 27B, and FIG. 27C are process views showing manufacturing processes of the outer shell forming a part of the exhaust passage heating unit shown in FIG. 22;

FIG. 28A, FIG. 28B, and FIG. 28C are process views showing manufacturing processes of the outer shell forming a part of the exhaust passage heating unit shown in FIG. 22;

FIG. 29 is a sectional view showing still another embodiment of the exhaust passage heating unit according to the present invention;

FIG. 30A and FIG. 30B are enlarged sectional view showing a part of the exhaust passage heating unit shown in FIG. 29 in an enlarged manner;

FIG. 31 is a developed view showing the general construction of a resistive heating element forming a part of the exhaust passage heating unit shown in FIG. 29;

FIG. 32 is a sectional view showing still another embodiment of the exhaust passage heating unit according to the present invention;

FIG. 33 is a sectional view showing still another embodiment of the exhaust passage heating unit according to the present invention;

FIG. 34A and FIG. 34B are sectional views showing still another embodiment of the exhaust passage heating unit according to the present invention; and

FIG. 35 is a developed view showing a general construction of a resistive heating element forming a part of the exhaust passage heating unit shown in FIG. 34A and FIG. 34B.

### BEST MODE FOR CARRYING OUT THE INVENTION

Hereinafter, best modes of the present invention are described with reference to the accompanying drawings.

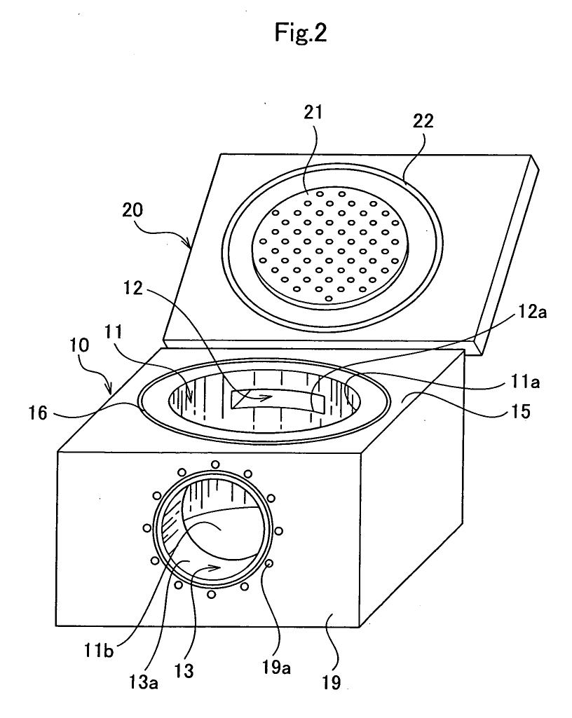

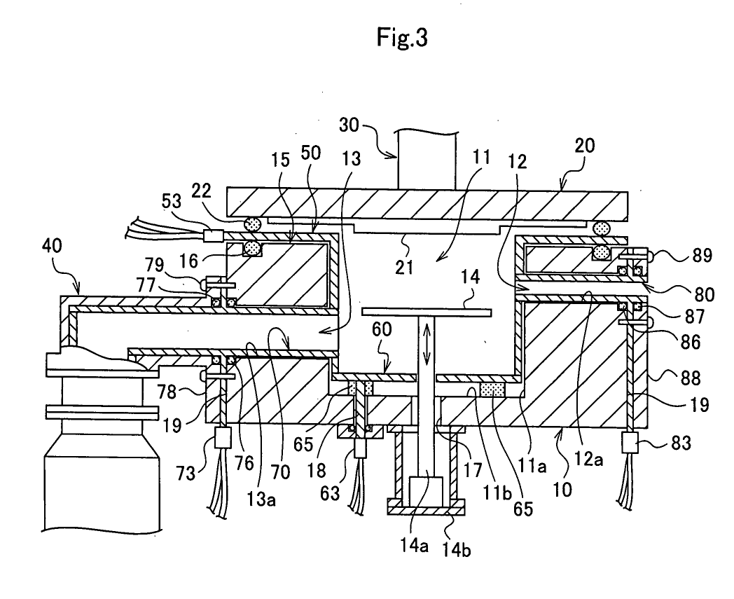

A semiconductor manufacturing device (CVD device) having the heating unit according to the present invention includes, as shown in FIG. 2 and FIG. 3, a main body 10, a cover 20 connected to the main body 10 so as to open and close the main body 10, a supply line 30 for supplying a processing gas or the like connected to the cover 20, and an exhaust line 40 that is connected to the main body 10 and that includes a turbo molecular pump (TMP) on the downstream side.

The main body 10 has a processing chamber 11 forming a cylindrical space for housing a semiconductor wafer and applying predetermined processes, a transferring passage 12 with a roughly rectangular section for putting in and taking out wafers of the processing chamber 11, an roughly cylindrical exhaust passage 13 for exhausting a processing gas inside the processing chamber, and a susceptor 14 on which wafers are placed inside the processing chamber 11. The susceptor 14 is driven vertically by a drive mechanism 14a that is detachably linked, and is insulated from the outside by the cover member 14b and is vacuum-sealed.

The cover 20 has a shower head 21 that demarcates a supply passage for supplying a processing gas to the inside of the processing chamber 11, and an O-ring 22 as a sealing member, and so on.

In addition, in the main body 10, as a heating unit, two chamber heating units 50 and 60 for heating the inner wall face of the processing chamber 11, an exhaust passage heating unit 70 for heating the inner wall face of the exhaust passage 13, a transferring passage heating unit 80 for heating the inner wall face of the transferring passage 12, and so on are provided.

The main body 10 is formed of, as shown in FIG. 2 and FIG. 3, an inner wall face (side wall face) 11a and inner wall face (bottom wall face) 11b that demarcate the processing chamber 11, an inner wall face 12a that demarcates the transferring passage 12, an inner wall face 13a that demarcates the exhaust passage 13, an upper face 15 to which the cover 20 is joined, an O-ring 16 as a sealing member provided on the upper face 15, through holes 17 and 18 formed in the bottom wall face (inner wall face 11b), an outer wall face 19, attaching screw holes 19a provided in the outer wall face 19, and so on.

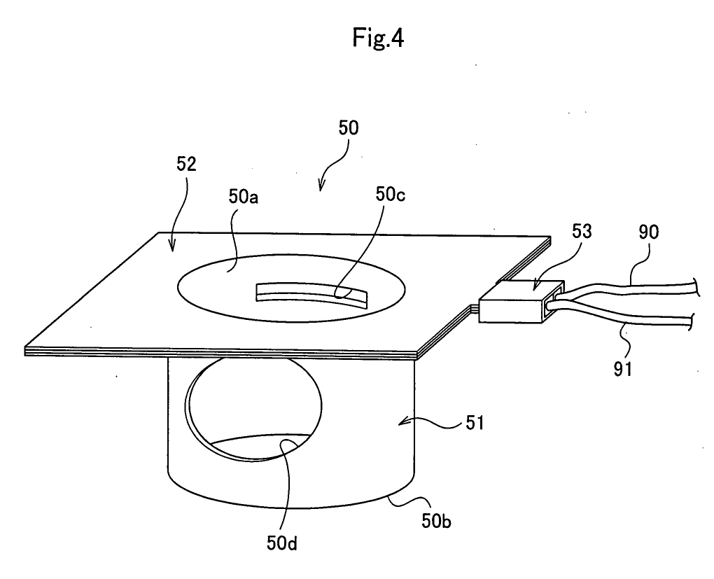

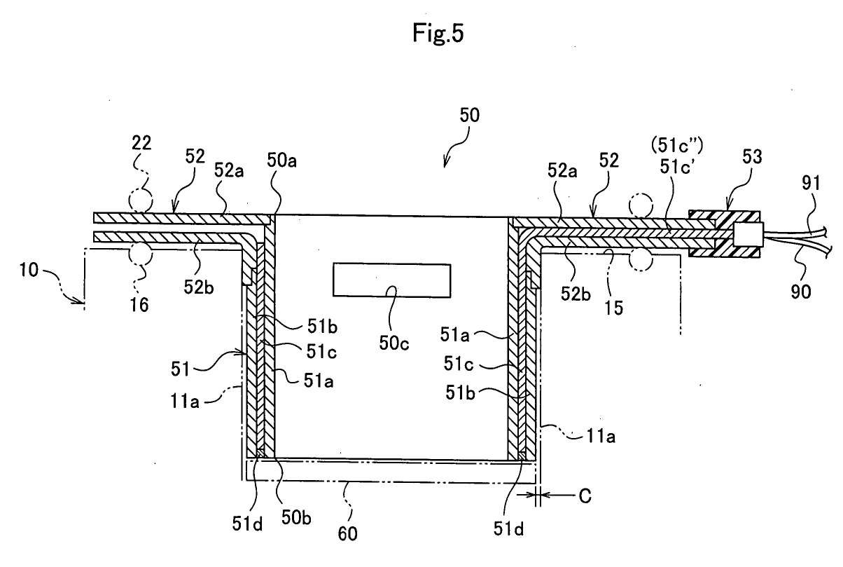

The chamber heating unit 50 is formed of, as shown in FIG. 4 and FIG. 5, a cylindrical heating main body 51 to be disposed adjacent to the inner wall face (side wall face) 11a of the processing chamber 11 so as to cover it and so as to demarcate an upper end opening 50a, a lower end opening 50b, a rectangular opening 50c corresponding to the transferring passage 12, and a circular opening 50d corresponding to the exhaust passage 13, an attaching portion 52 formed in a roughly rectangular flange shape integrally with the upper end of the heating main body 51, a connector (connection box) 53 provided on the outer end of the attaching portion 52, and so on.

The heating main body 51 is formed of thin and cylindrical inner shell 51a and outer shell 51b as a pair of metal plates, a thin plate-shaped resistive heating element 51c sandwiched and covered between the both shells 51a and 51b, a spacer 51d that joins the edges of the both shells 51a and 51b and seals up the resistive heating element 51c, and so on.

The spacer 51d is provided at the edges (edges of the lower end opening 50b, the rectangular opening 50c, and the circular opening 50d) in regions to be exposed to a processing gas in the edges of the both shells 51a and 51b to completely prevent the resistive heating element 51c from being exposed to the processing gas or the like.

The attaching portion 52 is formed of a flange 52a joined to the inner shell 51a and a flange 52b joined to the outer shell 51b, and between the both flanges 52a and 52b, a conducting lead 51c′ connected to the resistive heating element 51c and a lead 51c″ of a thermocouple as a temperature sensor for measuring the temperature of the resistive heating element 51c are sandwiched and drawn to the connector 53. Namely, the flanges 52a and 52b are not completely sealed up but are opened to the outside. At the connector 53, a power supply cable 90 is connected to the lead 51c′, and a cable 91 to be connected to a measuring instrument is connected to the lead 51c″.

Herein, in order to increase the heat transfer efficiency, the inner shell 51a and the outer shell 51b are formed of a material that has a plate thickness of approximately 0.5 mm and has corrosion resistance to the processing gas. As this material, for example, stainless steel, titanium, aluminum alloy, nickel-cobalt alloy, or ceramics made of any of aluminum oxide, silicon carbide, aluminum nitride, silicon nitride, and silicon oxide is preferably used. It is also possible that corrosion resistance is obtained by coating, and in this case, as a coating material, alumina(Al₂O₃), SiC, AlN, Si₃N₄ or the like is preferable. In addition, the same material can be used for the flanges 52a and 52b. Furthermore, by smoothing the surfaces of the shells 51a and 51b to be exposed to a high temperature, more desirably, finishing the surfaces to a surface roughness level of Ra≦0.1, even if by-products are deposited, the deposited by-products can be easily removed during maintenance.

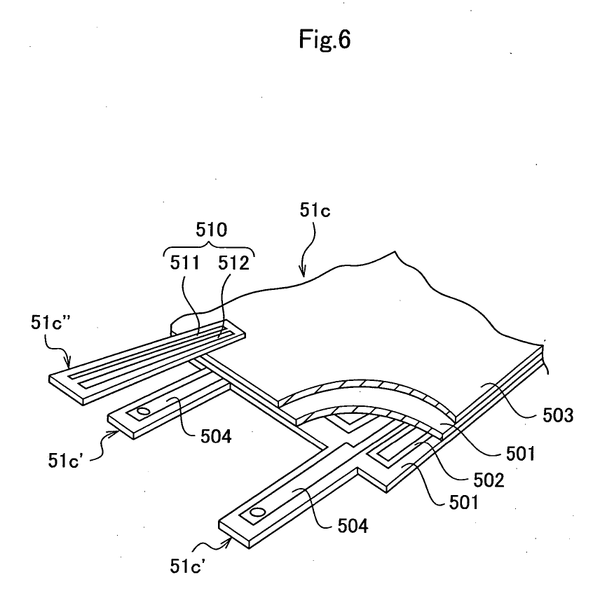

The resistive heating element 51c is formed of, as shown in FIG. 6, a flexible insulating film 501, an electric heating resistive foil 502 laid in zigzag and sandwiched on the insulating film 501, and a heat conducting foil 503 to disperse heat generated at the resistive foil 502 to the entirety, and from a part thereof, a lead foil 504 forming the lead 51c′ is drawn out. In the resistive heating element 51c, a thermocouple 510 including wires 511 and 512 as a temperature sensor for detecting the temperature of the resistive heating element is provided, and the lead 51c′ is drawn out of a part thereof. The resistive heating element 51c is disposed so that the heat conducting foil 503 comes into contact with the inner shell 51a.

Herein, the insulating film 501 is made of a resin material such as a polyimide resin excellent in heat resistance, and the heat conducting foil 503 is formed of a metal foil of stainless steel or the like having a thickness of approximately 50 μm.

Herein, as the resistive heating element 51c, a polyimide heater using a polyimide film is employed, however, other than this, a silicon rubber heater, a mica heater, a sheath heater, or the like can be employed. Thus, by using a flexible thin-film resistive heating element, it can be formed into various shapes corresponding to the inner wall faces.

The chamber heating unit 50 is constructed so that, as shown in FIG. 3 and FIG. 5, the heating main body 51 is inserted into the processing chamber 11 and the attaching portion 52 is placed on the upper face 15 so that a slight space C is left between the outer shell 51b and the inner wall face 11a, whereby the attaching operation is completed, and when the cover 20 is closed, the O-rings 22 and 16 come into contact with the flanges 52a and 52b of the attaching portion 52, respectively, whereby the inside of the processing chamber 11 is insulated from the outside and is vacuum sealed.

Thus, by providing the attaching portion 52 on the heating main body 51, the attaching and detaching operations can be easily performed, and between the heating main body 51 and the inner wall face 11a, a space (vapor phase) is left, whereby the attaching and detaching operations become easier and the heat transmitted to the outside from the heating main body 51 is reduced and the heating efficiency by the heating main body 51 further increases.

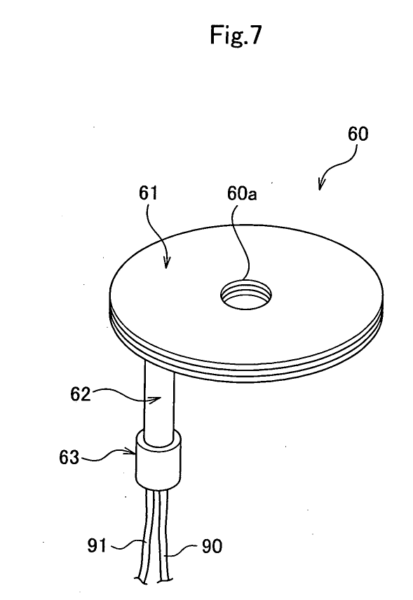

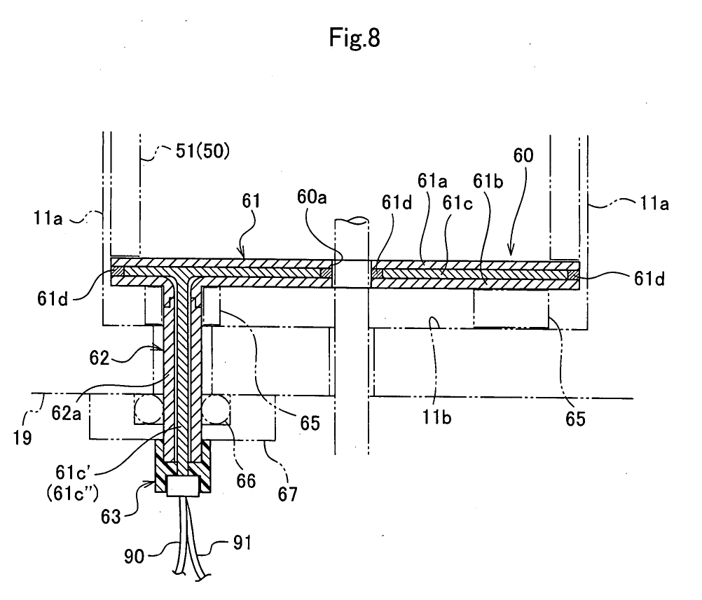

The chamber heating unit 60 is formed of, as shown in FIG. 7 and FIG. 8, a disk-shaped heating main body 61 to be disposed to face and cover the inner wall face (bottom wall face) 11b of the processing chamber 11 to demarcate the central opening 60a, an attaching portion 62 as a straight pipe formed integrally with and extending from the lower face of the heating main body 61, and a connector 63 provided at the lower end of the attaching portion 62.

The heating main body 61 is formed of, as shown in FIG. 8, thin and disk-shaped inner shell 61a and outer shell 61b as a pair of metal plates, a thin plate-shaped resistive heating element 61c sandwiched and covered between the shells 61a and 61b, a spacer 61d that joins the edges (inner circumferential edge of the central opening 60a and outer circumferential edge) of the shells 61a and 61b and seals up the resistive heating element 61c.

The attaching portion 62 is formed of a straight pipe 62a joined to the outer shell 61b, and through the straight pipe 62a, a conducting lead 61c′ connected to the resistive heating element 61c and a lead 61c″ of a thermocouple as a temperature sensor for measuring the temperature of the resistive heating element 61c are inserted and drawn to the connector 63. Then, at the connector 63, a power supply cable 90 is connected to the lead 61c′, and a cable 91 to be connected to a measuring instrument is connected to the lead 61c″.

As the inner shell 61a, the outer shell 61b, and the resistive heating element 61c, the same constructions and materials as those in the aforementioned chamber heating unit 50 are applied.

As shown in FIG. 3 and FIG. 8, prior to attaching of the chamber heating unit 50, the chamber heating unit 60 is inserted into the processing chamber 11 from above while the susceptor 14 is removed, and while the heating main body 61 is made to face the inner wall face (bottom wall face) 11b of the processing chamber 11, the lower surface thereof (outer shell 61b) is supported by a heat insulating material 65 and the attaching portion 62 is made to project from the outer wall face 19 of the main body 10 and the O-ring 66 as a sealing member is externally fitted and then fixed by a two-divided fixing member 67, whereby the chamber heating unit 60 is completely attached.

As the heat insulating member 65, one made of alumina ceramics (Al₂O₃) is employed.

Thus, by providing the attaching portion 62 in the heating main body 61, the attaching and detaching operations can be easily performed, and by leaving a space (vapor phase) and providing the heat insulating member 65 between the heating main body 61 and the inner wall face 11b, the heat transmitted from the heating main body 61 to the outside is reduced and the heating efficiency by the heating main body 61 further increases.

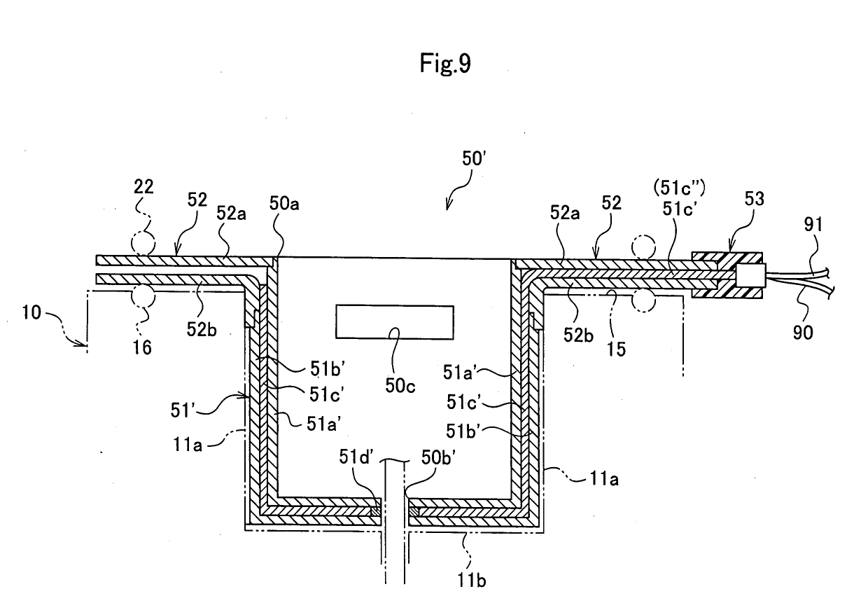

FIG. 9 shows a partially changed chamber heating unit 50, wherein the same constructional points as in the above-described embodiment are attached with the same symbols and description thereof is omitted.

Namely, this chamber heating unit 50′ is formed of, as shown in FIG. 9, a bottomed cylindrical heating main body 51′ disposed so as to be adjacent to and cover the inner wall faces (side wall face and bottom wall face) 11a and 11b of the processing chamber 11, an attaching portion integrally formed in a roughly rectangular flange shape at the upper end of the heating main body 51′, a connector 53 provided at the outer end of the attaching portion 52, and so on to demarcate an upper end opening 50a, a central opening 50b′, a rectangular opening 50c corresponding to the transferring passage 12, and a circular opening 50d corresponding to the exhaust passage 13.

The heating main body 51′ is formed of bottomed thin cylindrical inner shell 51a′ and outer shell 51b′ as a pair of metal plates, a thin-plate resistive heating element 51c′ sandwiched and covered between the shells 51a′ and 51b′, a spacer 51d′ that join the edges of the shells 51a′ and 51b′ and seals up the resistive heating element 51c′, and so on.

The spacer 51d′ is provided at the edges (edges of the central opening 50b′, the rectangular opening 50c, and the circular opening 50d) in the regions to be exposed to a processing gas in the edges of the shells 51a′ and 51b′ to completely prevent the resistive heating element 51c′ from being exposed to the processing gas or the like.

In this chamber heating unit 50′, the above-described chamber heating units 50 and 60 are formed integrally, so that as well as realizing efficient heating of the inner wall faces of the processing chamber 11 and preventing or minimizing adhesion of the by-products, the number of parts is reduced and the attaching and detaching operations are further simplified.

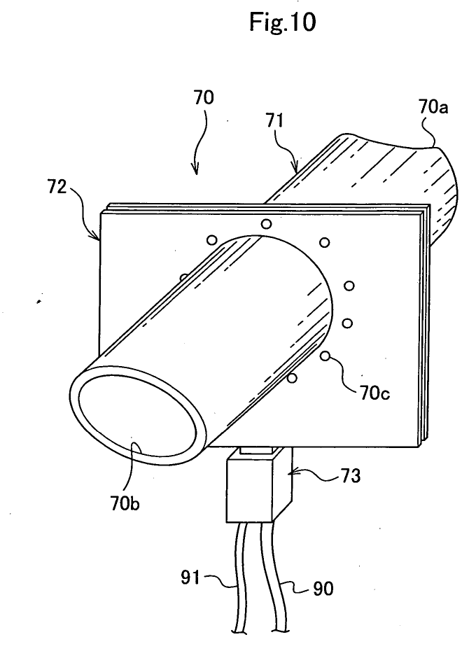

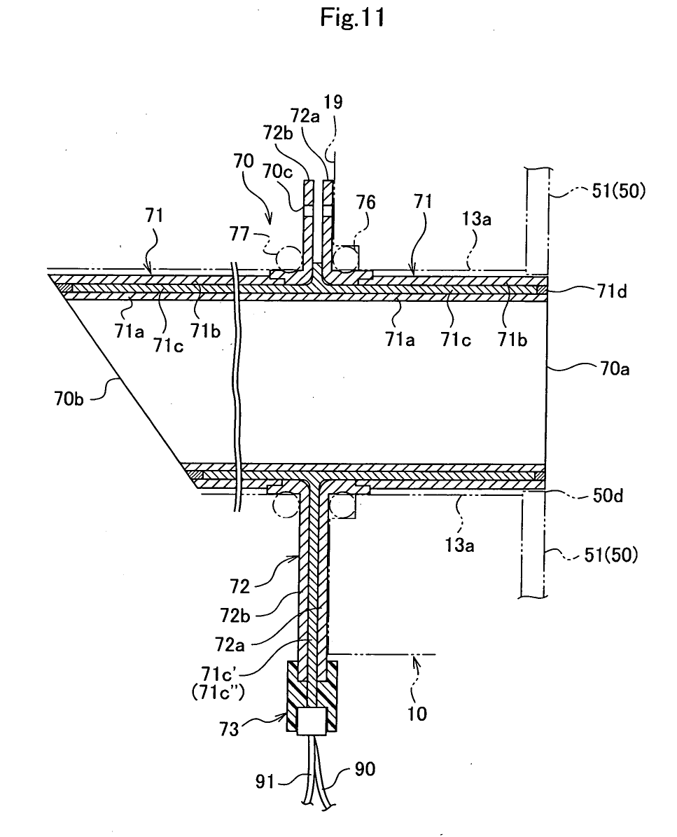

The exhaust passage heating unit 70 is formed of, as shown in FIG. 3, FIG. 10, and FIG. 11, a cylindrical heating main body 71 that is disposed so as to be adjacent to and cover the inner wall face 13a of the exhaust passage 13, an attaching portion 72 integrally formed in a roughly rectangular flange shape at the outer circumference of the heating main body 71, and a connector 73 provided at the outer end of the attaching portion 72, and so onto demarcate an opening 70a on the processing chamber 11 side, an opening 70b on the exhaust line 40 side, and an attaching hole 70c.

The heating main body 71 is formed of cylindrical thin inner shell 71a and outer shell 71b as a pair of metal plates, a thin plate resistive heating element 71c sandwiched and covered between the shells 71a and 71b, and a spacer 71d that joins the edges of the shells 71a and 71b and seals up the resistive heating element 71c.

The spacer 71d is provided at the edges (edges of the openings 70a and 70b) in the regions to be exposed to the processing gas in the edges of the shells 71a ad 71b to completely prevent the resistive heating element 71c from being exposed to the processing gas or the like.

The attaching portion 72 is formed of flanges 72a and 72b joined to the outer shell 71b, and between the flanges 72a and 72b, a conducting lead 71c′ connected to the resistive heating element 71c and a lead 71c″ of a thermocouple as a temperature sensor for measuring the temperature of the resistive heating element 71c are sandwiched and drawn to the connector 73. Namely, the flanges 72a and 72b are not completely sealed up but are opened to the outside. At the connector 73, a power supply cable 90 is connected to the lead 71c′ and a cable 91 to be connected to the measuring instrument is connected to the lead 71c″.

As the inner shell 71a, the outer shell 71b, the flanges 72a and 72b, and the resistive heating element 71c, the same constructions and materials as those in the aforementioned chamber heating unit 50 are applied.

As shown in FIG. 3 and FIG. 11, the heating main body 71 is inserted into the exhaust passage 13 so that a slight space is left between the outer shell 71b and the inner wall face 13a, and while the O-rings 76 and 77 are attached, the attaching portion 72 is joined to the outer wall face 19 and a fixing plate 78 forming a part of the exhaust line is pressed from the outside and is fastened by a screw 79, whereby the exhaust passage heating unit 70 is completely attached and the exhaust passage 13 is insulated from the outside and is sealed in a vacuum state.

Thus, by providing the heating main body 71 with the attaching portion 72, the attaching and detaching operations can be easily performed, and by leaving a space (vapor phase) between the heating main body 71 and the inner wall face 13a, the attaching and detaching operations become easier and the heat transmitted from the heating main body 71 to the outside is reduced and this increases the heating efficiency of the heating main body 71.

Herein, the exhaust passage heating unit 70 is disposed at the upstream side of the turbo molecular pump, however, in the entire region of the exhaust line 40, for example, a similar sheet-like heating unit that is changed in shape as appropriate like an elbow pipe type or a straight pipe type, can be disposed.

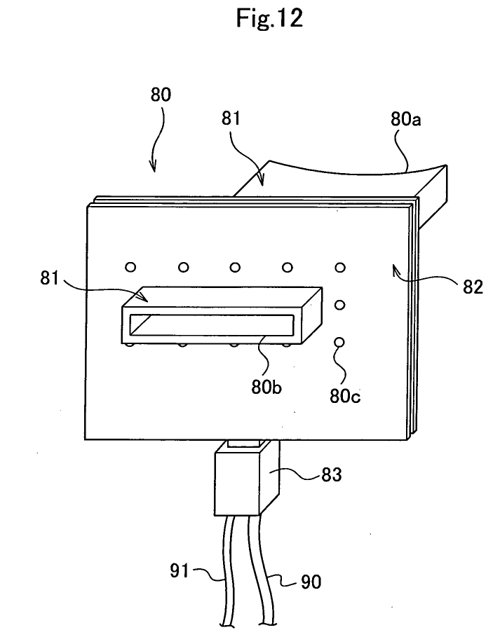

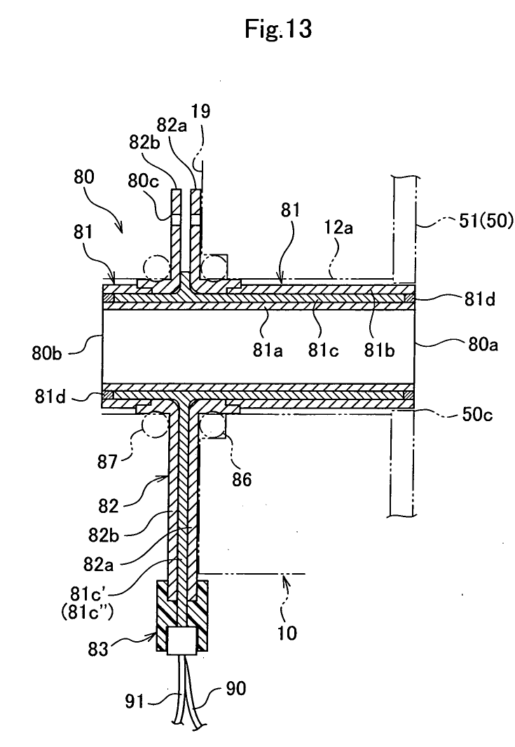

The transferring passage heating unit 80 is formed of, as shown in FIG. 3, FIG. 12, and FIG. 13, a cylindrical heating main body 81 having a roughly rectangular section disposed so as to be adjacent to and cover the inner wall face 12a of the transferring passage 12, an attaching portion 82 integrally formed in a roughly rectangular flange shape at the outer circumference of the heating main body 81, a connector 83 provided at the outer end of the attaching portion 82, and so on to demarcate an opening 80a on the processing chamber 11 side, an opening 80b that faces a gate valve of a transfer chamber to be used for carrying in and out a wafer, and an attaching hole 80c.

The heating main body 81 is formed of thin and rectangular cylindrical inner shell 81a and outer shell 81b as a pair of metal plates, a thin plate resistive heating element 81c sandwiched and covered between the shells 81a and 81b, and a spacer 81d that joins the edges of the shells 81a and 81b and seals up the resistive heating element 81c.

The spacer 81d is provided at the edges (edges of the openings 80a and 80b) in the regions to be exposed to the processing gas in the edges of the shells 81a and 81b, and completely prevents the resistive heating element 81c from being exposed to the processing gas or the like.

The attaching portion 82 is formed of flanges 82a and 82b joined to the outer shell 81b, and between the flanges 82a and 82b, a conducting lead 81c′ connected to the resistive heating element 81c and a lead 81c″ of a thermocouple as a temperature sensor for measuring the temperature of the resistive heating element 81c are sandwiched and drawn to the connector 83. Namely, flanges 82a and 82b are not completely sealed up but are opened to the outside. Then, at the connector 83, a power supply cable 90 is connected to the lead 81c′ and a cable 91 to be connected to the measuring instrument is connected to the lead 81c″.

As the inner shell 81a, the outer shell 81b, the flanges 82a and 82b, and the resistive heating element 81c, the same constructions and materials as those in the aforementioned chamber heating unit 50 are applied.

As shown in FIG. 3 and FIG. 13, the heating main body 81 is inserted into the transferring passage 12 so that a slight space is left between the outer shell 81b and the inner wall face 12a, and while rectangular annular rings 86 and 87 as sealing members are attached, the attaching portion 82 is joined to the outer wall face 19 and a fixing plate 88 is pressed from the outside and is fastened with a screw 89, whereby the transferring passage heating unit 80 is completely attached and the transferring passage 12 is insulated from the outside and is vacuum sealed.

Thus, by providing the heating main body 81 with the attaching portion 82, the attaching and detaching operations can be easily performed, a space (vapor phase) is left between the heating main body 81 and the inner wall face 12a, whereby the attaching and detaching operations become easier and the heat transmitted from the heating main body 81 to the outside is reduced and the heating efficiency of the heating main body 81 increases.

Next, attaching procedures of the chamber heating units 50 and 60, the exhaust passage heating unit 70, and the transferring passage heating unit 80 are described briefly.

First, the susceptor 14 is removed by opening the cover 20. Then, the chamber heating unit 60 is inserted into the processing chamber 11 and disposed in the bottom region.

Subsequently, the heating main body 51 of the chamber heating unit 50 is inserted to the inside of the processing chamber 11 and the attaching portion 52 is placed on the upper face 15.

Subsequently, while the transferring chamber is opened, the heating main body 81 of the transferring passage heating unit 80 is inserted into the transferring passage 12 and the front end thereof (rectangular opening 80a) is fitted into the opening 50c of the heating main body 51, and the attaching portion 82 is joined to the outer wall face 19 and is fixed by a fixing plate 88.

Subsequently, while removing the exhaust line 40, the heating main body 71 of the exhaust passage heating unit 70 is inserted into the exhaust passage 13 and the front end (opening 70a) is fitted into the circular opening 50d of the heating main body 51, and the attaching portion 72 is joined to the outer wall face 19 and is fixed by a fixing plate 78. Thereby, the heating units 50, 60, 70, and 80 are completely attached. On the other hand, the detaching operations are performed according to the reverse procedures.

Since all heating units 50, 60, 70, and 80 are thus smoothly attached and detached, even when a part needs to be replaced upon stopping the device, the stop period can be minimized and the operating time can be increased.

When the chamber heating unit 50′ is used in place of the chamber heating units 50 and 60, the attaching operation and the detaching operation are further simplified.

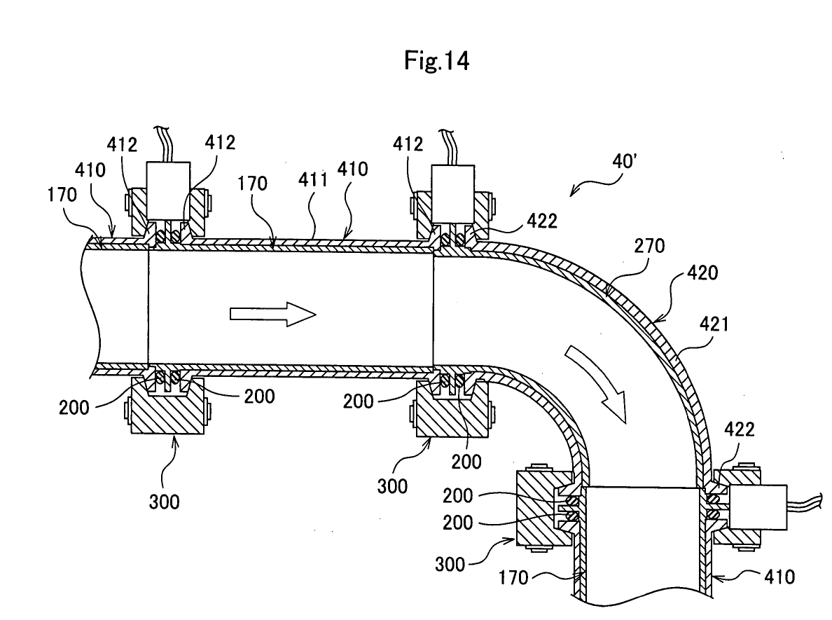

FIG. 14 shows another embodiment of the exhaust line and the exhaust passage heating unit in the semiconductor manufacturing device and a clamp mechanism.

This exhaust line 40′ includes a plurality of exhaust pipes (piping) 410 and 420 that are formed to be attachable and detachable and joined to each other as shown in FIG. 14, and inside the respective exhaust pipes 410 and 420, exhaust passage heating units 170 and 270 are disposed. Then, the exhaust pipes 410 and 420 are joined to each other by the clamp mechanisms 300 while sandwiching O-rings 200 as sealing members.

The exhaust pipe 410 has a straight cylinder part 411 that demarcates a straight exhaust passage and flange portions 412 formed into a sword guard shape while projecting outward radially at the connection ends of the straight cylinder part 411. The exhaust pipe 420 has a curved cylinder part 421 that demarcates a curved exhaust passage and flanges 422 formed into a sword guard shape projecting outward radially at the connection ends of the curved cylinder part 421.

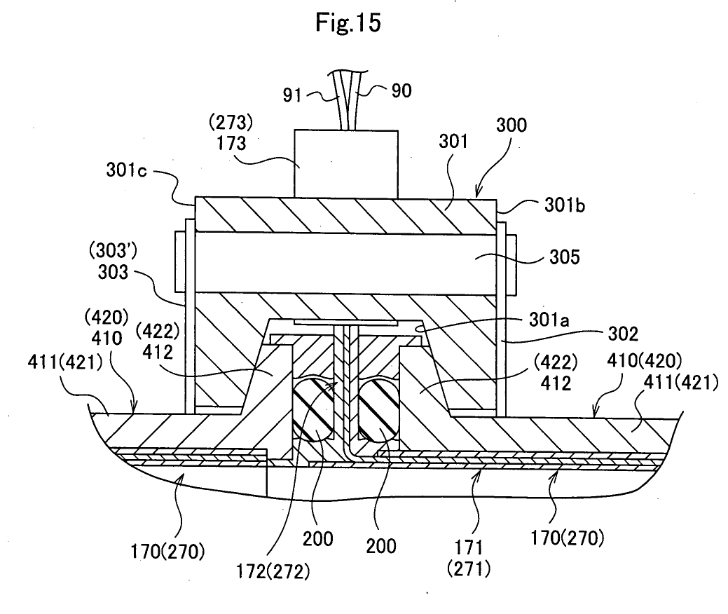

Herein, the flange portions 412 and 412 and the flange portions 412 and 422 are formed to face each other in the connecting direction as shown in FIG. 14 and FIG. 15, and are formed so as to have tapered sectional shapes that become thinner outward radially by inclining the faces opposite the facing sides.

The clamp mechanism 300 includes, as shown in FIG. 14 through FIG. 16, a plurality of clamp blocks 301 having grooves 301a with roughly V-shaped sections for receiving the flange portions 412 and 412 and the flange portions 412 and 422 so as to press these closer to each other, a plurality (herein, four) of first link plates 302 that join one side portions 301b of the clamp blocks 301 to each other, a plurality (herein, four) of second link plates 303 that join the other side portions 301c of the clamp blocks 301 to each other, and a bolt 304 as a fastening member rotatably supported on one clamp block 301 and a female screw that is formed on the other clamp block 301 and is screwed to the bolt 304.

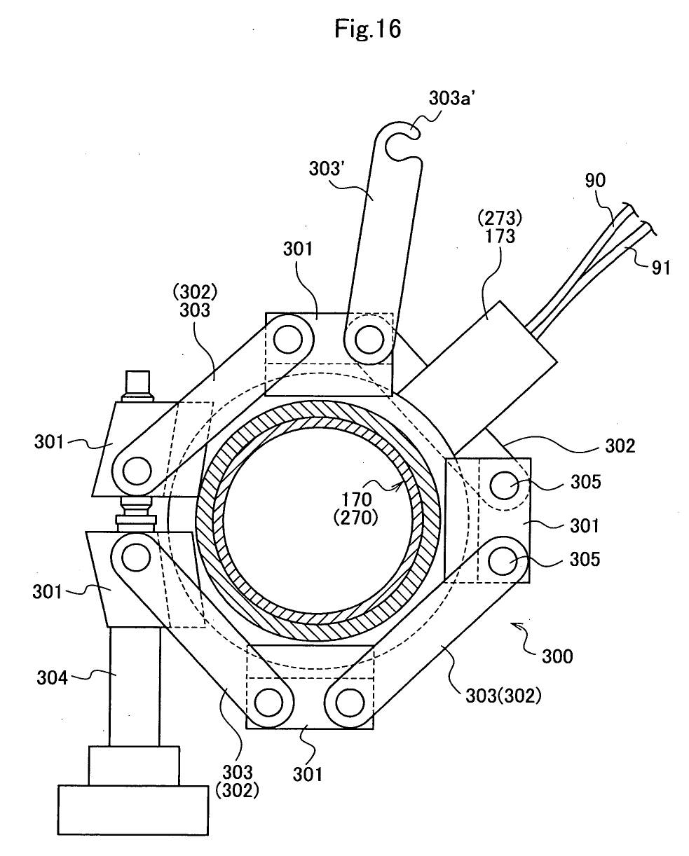

One link plate 303′ of the plurality of link plates 303 has, as shown in FIG. 16, one end 303a′ formed into a hook shape that can be latched on and released from a pin 305 of the clamp block 301.

While the attaching portion 172 or 272 described later of the exhaust passage heating unit 170 or 270 is sandwiched between the flange portions 412 and 412 or the flange portions 412 and 422 via the O-rings 200, the clamp mechanism 300 is wound around the outer circumference of the flange portions 412 and 412 or 412 and 422 and the bolt 304 is screwed, whereby the exhaust pipes 410 and 410 or 410 and 420 are joined to each other.

Thus, the clamp mechanism 300 is formed into a chain shape, so that the exhaust pipes 410 and 410 or 410 and 420 attached with the exhaust passage heating unit 170 or 270 can be easily joined and the joint can be easily released.

Particularly, since at least one link plate 303′ can be latched on and released from the clamp block 301, when the connector 173 or 273 formed at the attaching portion 172 or 272 of the exhaust passage heating unit 170 or 270 is comparatively long or the cable 90 or 91 is connected thereto, the releasable link plate 303′ is released in advance and the connector 173 or 273 or the cable 90 or 91 is inserted, and then the link plate 303′ is latched on the clamp block 301, whereby the exhaust passage heating unit 170 or 270 can be assembled easily.

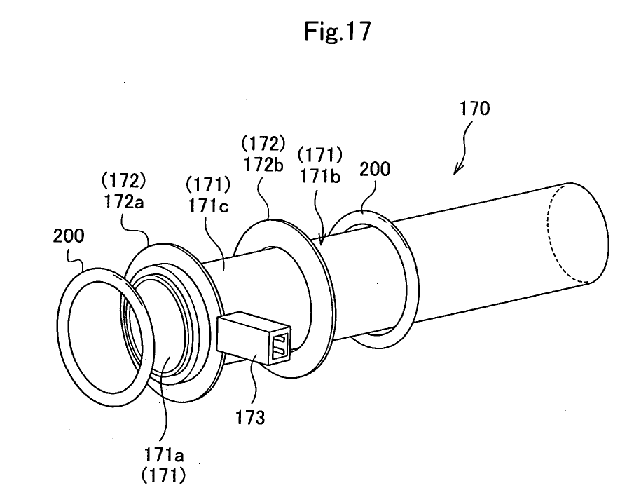

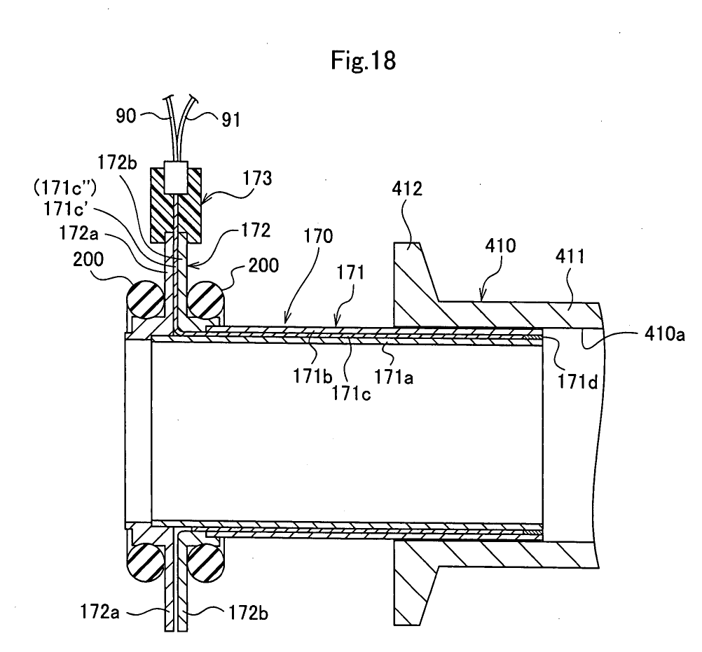

The exhaust passage heating unit 170 is formed of, as shown in FIG. 17 and FIG. 18, a cylindrical heating main body 171 disposed so as to be adjacent to and cover the inner wall face 410a of the exhaust pipe 410 (exhaust passage), an attaching portion 172 integrally formed in an annular and flange shape at the outer circumference of the heating main body 171, a connector 173 provided at the radial outer end of the attaching portion 172, and so on.

The heating main body 171 is formed of thin and cylindrical inner shell 171a and outer shell 171b as a pair of metal plates, a thin plate resistive heating element 171c sandwiched and covered between the shells 171a and 171b, a spacer 171d that joins the edges of the shells 171a and 171b and seals up the resistive heating element 171c, and so on.

The spacer 171d is provided at edges in the regions exposed to the processing gas in the edges of the shells 171a and 171b to completely prevent the resistive heating element 171c from being exposed to the processing gas or the like.

The attaching portion 172 is formed of a flange 172a joined to the inner shell 171a and a flange 172b joined to the outer shell 171b, and between the flanges 172a and 172b, a conducting lead 171c′ connected to the resistive heating element 171c and a lead 171c″ of a thermocouple as a temperature sensor for measuring the temperature of the resistive heating element 171c are sandwiched and drawn to the connector 173. Namely, the flanges 172a and 172b are not completely sealed up but are opened to the outside. At the connector 173, a power supply cable 90 is connected to the lead 171c′ and a cable 91 to be connected to the measuring instrument is connected to the lead 171c″.

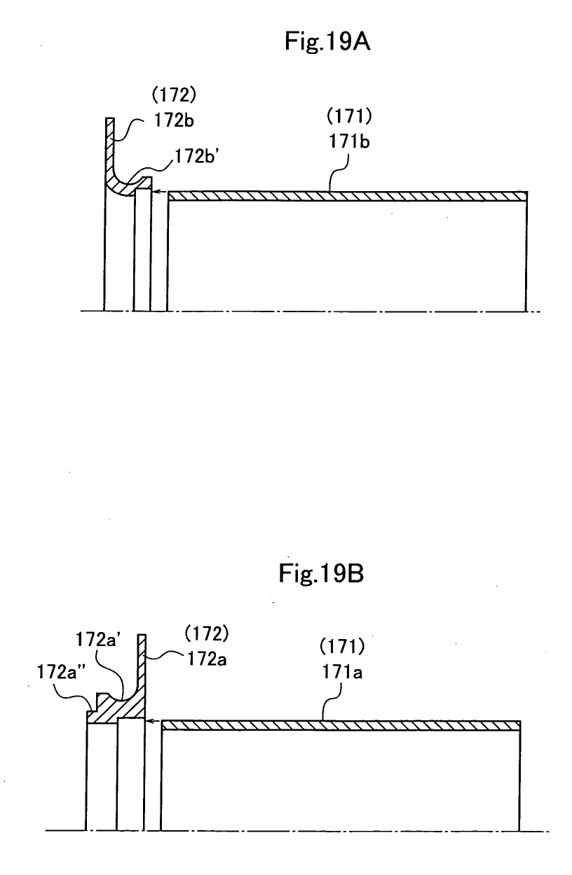

The outer shell 171b and the flange 172b are joined by welding (for example, TIG welding, plasma welding, laser welding, etc.) or brazing after they are formed separately from each other as shown in FIG. 19A. On the flange 172b, an annular groove 172b′ in which the O-ring 200 is fitted is formed.

The inner shell 171a and the flange 172a are formed separately from each other, and are then joined to each other by welding (for example, TIG welding, plasma welding, laser welding, etc.) or brazing or the like as shown in FIG. 19B. On the flange 172a, an annular groove 172a′ in which the O-ring 200 is fitted and an annular convex portion 172a″ for positioning are formed.

As the inner shell 171a, the outer shell 171b, the flanges 172a and 172b, and the resistive heating element 171c, the same materials or the same constructions and materials as those in the aforementioned chamber heating unit 50 are applied.

As shown in FIG. 18, the heating main body 171 is inserted into the exhaust passage so that the outer shell 171b comes into close contact with the inner wall face 410a or a slight space is left between the outer shell and the inner wall face 410a, and while attaching the O-rings 200, the attaching portion 172 is sandwiched between the flange portions 412 and 412 and the flange portions 412 and 422 and is fastened by the above-described clamp mechanism 300, whereby the exhaust passage heating unit 170 is completely attached, and the exhaust passage is insulated from the outside and sealed in a vacuum state. Thus, by providing the attaching portion 172 on the heating main body 171, the attaching and detaching operations can be easily performed.

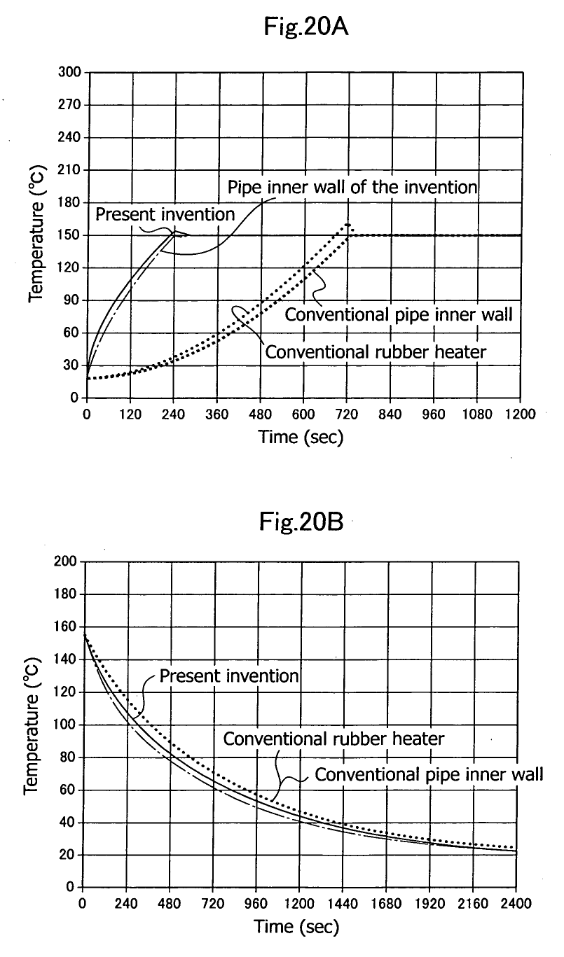

Herein, comparing the temperature rising characteristics and temperature lowering characteristics of the exhaust passage heating unit 170 and a conventional rubber heater, the results shown in FIG. 20A and FIG. 20B were obtained. On the assumption that the atmosphere temperature was 20° C. and still air at 20° C. existed inside the exhaust passage, the temperature rising characteristics when applying 108W to the resistive heating element 171c and the heater, and temperature lowering characteristics from 150° C. were analyzed.

With respect to the temperature rising characteristics, as shown in FIG. 20A, the time required until the inner wall temperature of the exhaust pipe reached approximately 150° C. was 240 seconds when using the exhaust passage heating unit 170 of the present invention although it was 720 seconds when using the conventional rubber heater. Namely, the time until the inner wall reaches a predetermined temperature can be remarkably reduced, and therefore, the energy use efficiency is significantly improved.

With respect to the temperature lowering characteristics, the time required until the inner wall face temperature of the exhaust pipe lowered from 150° C. to 80° C. was 420 seconds when using the exhaust passage heating unit 170 of the present invention although it was 540 seconds when using the conventional rubber heater as shown in FIG. 20B, and the time until the inner wall temperature lowers to a predetermined temperature can be shortened. Namely, cooling-down is quick, so that the time until the device is lowered in temperature and a cleaning gas of NF₃, ClF₃, or the like is made to flow after finishing the processes can be shortened.

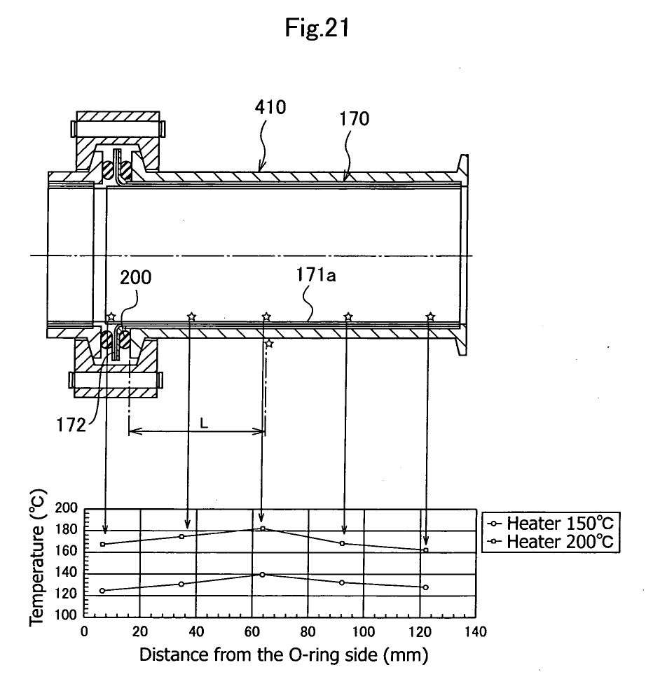

Furthermore, when the temperature distribution in the axial direction in the case where the exhaust passage heating unit 170 was attached to the exhaust pipe 410 was measured, the results shown in FIG. 21 were obtained. With respect to the measuring points, the temperatures at 5 points in the axial direction of the inner shell 171a and one point of the outer circumferential face of the exhaust pipe 410 at a distance L of 50 mm from the connection end face were measured. Herein, the temperature distribution was measured in each of the cases where the temperature of the resistive heating element (heater) 171c was 150° C. and 200° C.

As a result, as shown in FIG. 21, in the temperature distribution, the temperature of the inner shell 171a becomes higher toward the axial center and becomes lower gradually toward both ends. When the temperature of the resistive heating element 171c was raised to 150° C., the center reached approximately 140° C. and both ends reached approximately 120° C., and when the temperature of the resistive heating element 171c was raised to 200° C., the center reached approximately 180° C. and both ends reached approximately 160° C., and the temperature differences between the center and both ends are within 20° C.

The temperature of the exhaust pipe 410 was raised to 130.8° C. when the temperature of the resistive heating element 171c was 150° C., and was raised to 173.3° C. when the temperature of the resistive heating element 171c was 200° C., and this temperature rise is at almost the same level as that of the temperature of the inner shell 171a.

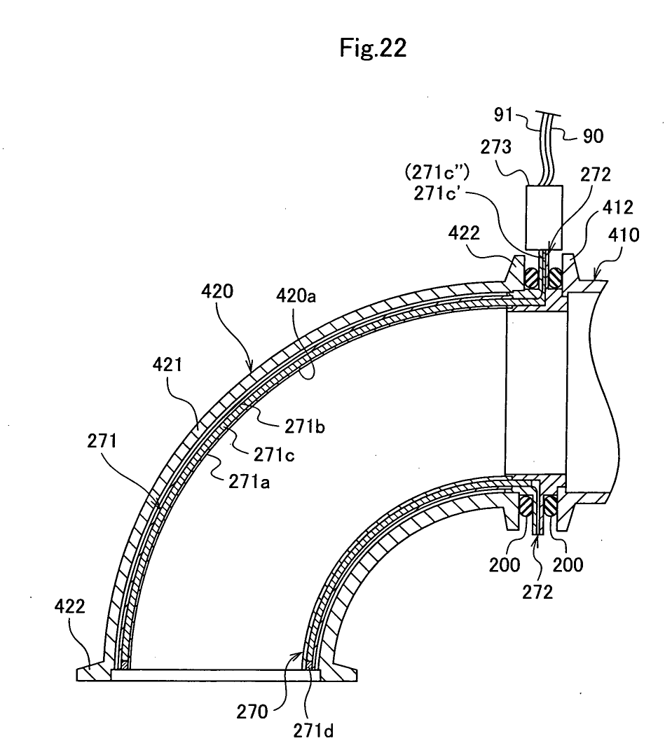

The exhaust passage heating unit 270 is formed of, as shown in FIG. 22 through FIG. 26, a heating main body 271 that is cylindrical and curved into an arc and disposed so as to be adjacent to and cover the inner wall face 420a of the curved exhaust pipe 420 (exhaust passage), and an attaching portion 272 integrally formed into an annular and flange shape on the outer circumference of the heating main body 271, a connector 273 provided at the radial outer end of the attaching portion 272, and so on.

The heating main body 271 is formed of thin and curved cylindrical inner shell 271a and outer shell 271b as a pair of metal plates, a thin plate-shaped resistive heating element 271c sandwiched and covered between the shells 271a and 271b, a spacer 271d that joins the edges of the shells 271a and 271b and seals up the resistive heating element 271c, and so on.

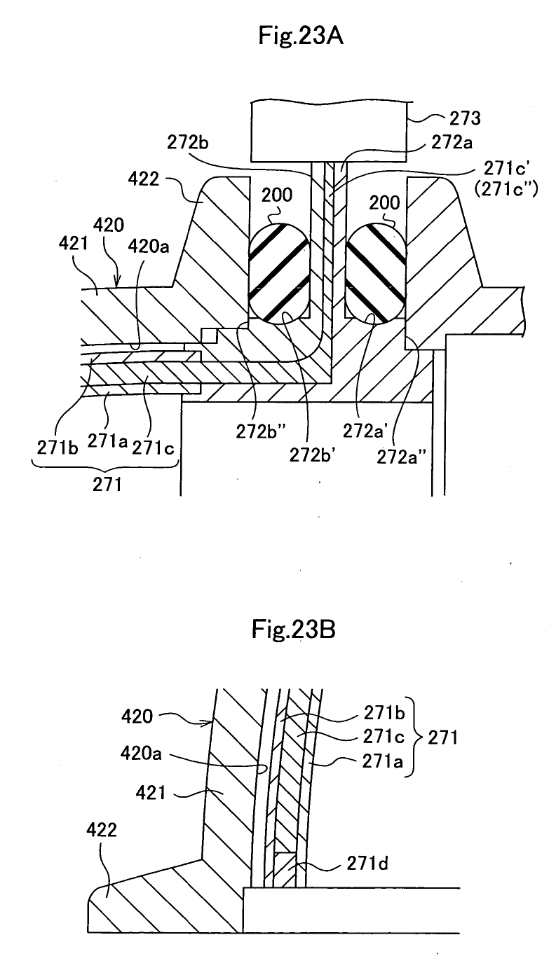

The spacer 271d is provided at edges in the regions to be exposed to the processing gas in the edges of the shells 271a and 271b as shown in FIG. 23B to completely prevent the resistive heating element 271c from being exposed to the processing gas or the like.

The attaching portion 272 is formed of a flange 272a joined to the inner shell 271a and a flange 272b joined to the outer shell 271b as shown in FIG. 23A, and between the flanges 272a and 272b, a conducting lead 271c′ connected to the resistive heating element 271c and a lead 271c″ of a thermocouple as a temperature sensor for measuring the temperature of the resistive heating element 271c are sandwiched and drawn to the connector 273. Namely, the flanges 272a and 272b are not completely sealed up but are opened to the outside. At the connector 273, a power supply cable 90 is connected to the lead 271c′ and a cable 91 to be connected to the measuring instrument is connected to the lead 271c″.

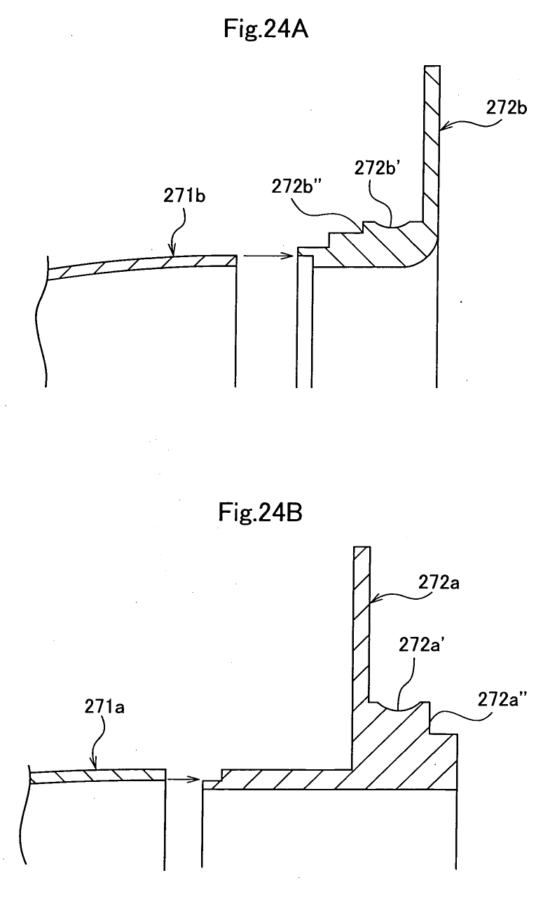

The outer shell 271b and the flange 272b are formed separately from each other and are then joined by welding (for example, TIG welding, plasma welding, laser welding, etc.) or brazing, etc., as shown in FIG. 24A. On the flange 272b, an annular groove 272b′ in which the O-ring 200 is fitted and an annular convex portion 272b″ for positioning are formed.

The inner shell 271a and the flange 272a are formed separately from each other and are then joined by welding (for example, TIG welding, plasma welding, laser welding, etc.) or brazing, etc., as shown in FIG. 24B. On the flange 272a, an annular groove 272a′ in which the O-ring 200 is fitted and an annular convex portion 272a″ for positioning are formed.

As the inner shell 271a, the outer shell 271b, and the flanges 272a and 272b, the same materials as those in the aforementioned chamber heating unit 50 are applied.

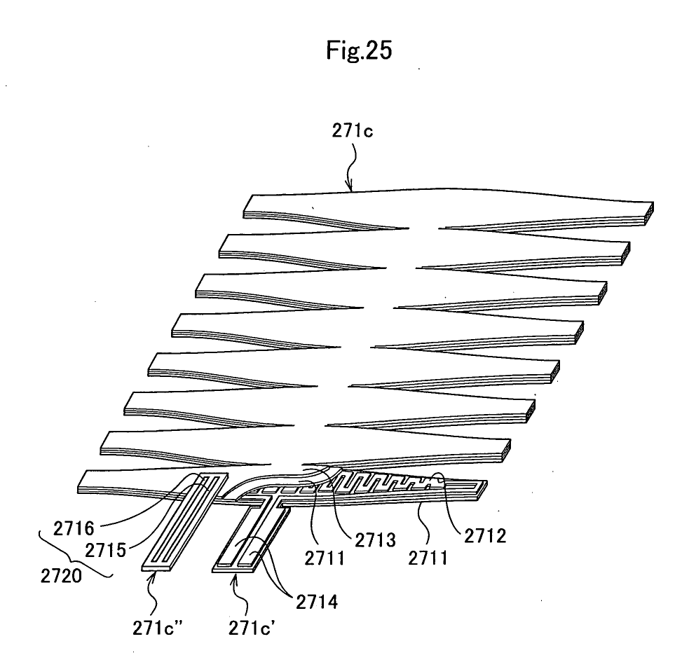

The resistive heating element 271c is formed of, as shown in FIG. 25, flexible insulating films 2711, an electric heating resistive foil 2712 laid in zigzag and sandwiched between the insulating films 2711, and a heat conducting foil 2713 that disperses heat generated at the resistive foil 2712 to the entirety, and from a part thereof, a lead foil 2714 forming the lead 271c′ is drawn out. Then, the resistive heating element 271c is provided with a plurality of notches so that it can be formed into a curved cylindrical shape.

In the resistive heating element 271c, a thermocouple 2720 including wires 2715 and 2716 as a temperature sensor for detecting the temperature of the resistive heating element is provided, and from a part thereof, the lead 271c″ is drawn out. The resistive heating element 271c is disposed so that the heat conducting foil 2713 is in contact with the inner shell 271a.

Herein, the insulating film 2711 is made of a resin material excellent in heat resistance such as a polyimide resin or the like, and the heat conducting foil 2713 is formed of a metal foil of stainless steel or the like with a thickness of approximately 50 μm.

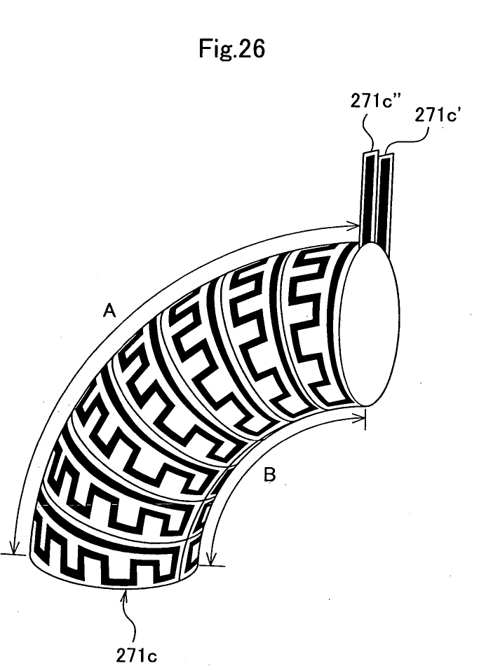

Furthermore, while the resistive heating element 271c is disposed between the shells 271a and 271b, as shown in FIG. 26, the region A thereof corresponds to the outside region of the exhaust pipe 420 (the region with a larger radius of curvature) and the region B thereof corresponds to the inside region of the exhaust pipe 420 (the region with a smaller radius of curvature). Then, in the resistive heating element 271c, the arrangement density, that is, the watt density of the resistive foil 2712 is set so as to be higher in the outside region A than in the inside region B. Thereby, in the curved outside region of the exhaust pipe 420, the heating value becomes higher, and in this region, deposits and growth of by-products can be efficiently prevented.

Herein, as the resistive heating element 271c, a polyimide heater using a polyimide film is employed, however, other than this, a silicon rubber heater, a mica heater, a sheath heater, or the like can be employed. Thus, by using a thin film resistive heating element with flexibility, it can be formed into various shapes corresponding to the inner wall face.

As shown in FIG. 22, FIG. 23A, and FIG. 23B, the heating main body 271 is inserted into the exhaust passage so that a slight space is left between the outer shell 271b and the inner wall face 420a of the exhaust pipe 420, and in a state in that the O-rings 200 are attached, the attaching portion 272 is sandwiched between the flange portions 422 and 412 and is fastened by the above-described clamp mechanism 300, whereby the exhaust passage heating unit 270 is completely attached, and the exhaust passage is insulated from the outside and is vacuum sealed. Thus, by providing the attaching portion 272 on the heating main body 271, the attaching and detaching operations can be easily performed.

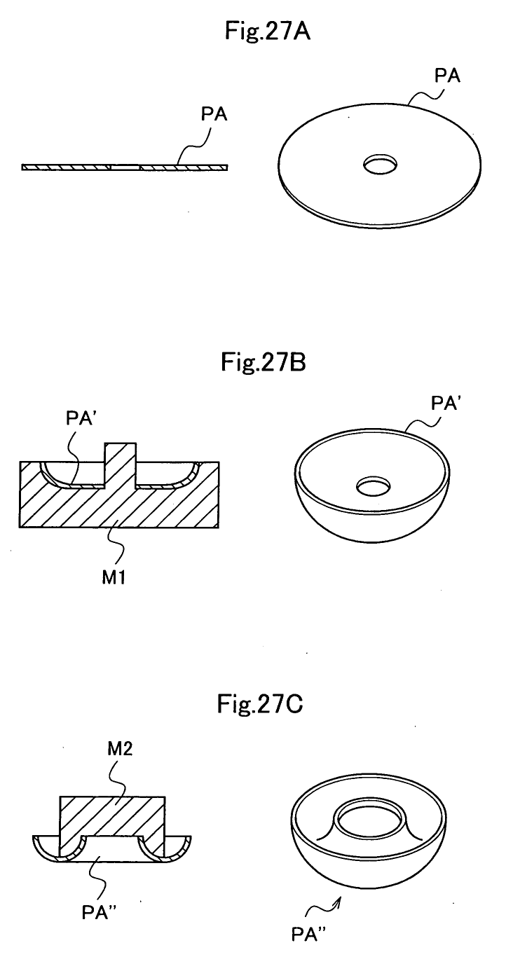

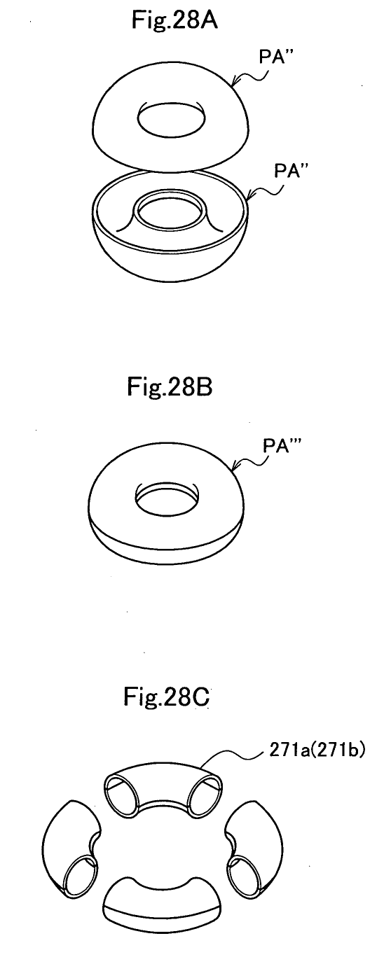

FIG. 27A through FIG. 28C show a method for manufacturing and assembling the outer shell 271b and the inner shell 271a.

First, as shown in FIG. 27A, a plate PA made of stainless steel or the like is cut into an annular shape. Next, as shown in FIG. 27B, the outer circumferential edge region of the plate PA is drawn by using a mold M1 so that its sectional shape becomes an arc shape. Then, as shown in FIG. 27C, the inner circumferential edge region of the plate PA′ is drawn by using a mold M2 so that its sectional shape becomes an arc shape to manufacture a half donut-shaped molding PA″.

Then, as shown in FIG. 28A, two moldings PA″ are prepared, and as shown in FIG. 28B, these are butted against each other and the outer circumferential edges and the inner circumferential edges are welded all around. Then, to remove residual stresses accumulated in the welding process, heat processing is applied. Then, by using the molds M1 and M2 again, corrective spinning is applied.

Thereafter, as shown in FIG. 28C, the completed donut-shaped structure PA′″ is divided equally into four by wire cutting or the like. Next, the cut sections cut by wire cutting are polished, whereby the outer shell 271b or the inner shell 271a is completed.

To the outer shell 271b and the inner shell 271a, a flange 272b and a flange 272a manufactured in advance by cutting, etc., are welded and spacers 271d are welded to the edges of the shells 271a and 271b, and thereafter, a resistive heating element 271c is curved and inserted between the shells 271a and 271b and a connector 273 is provided, whereby the exhaust passage heating unit 270 is completed.

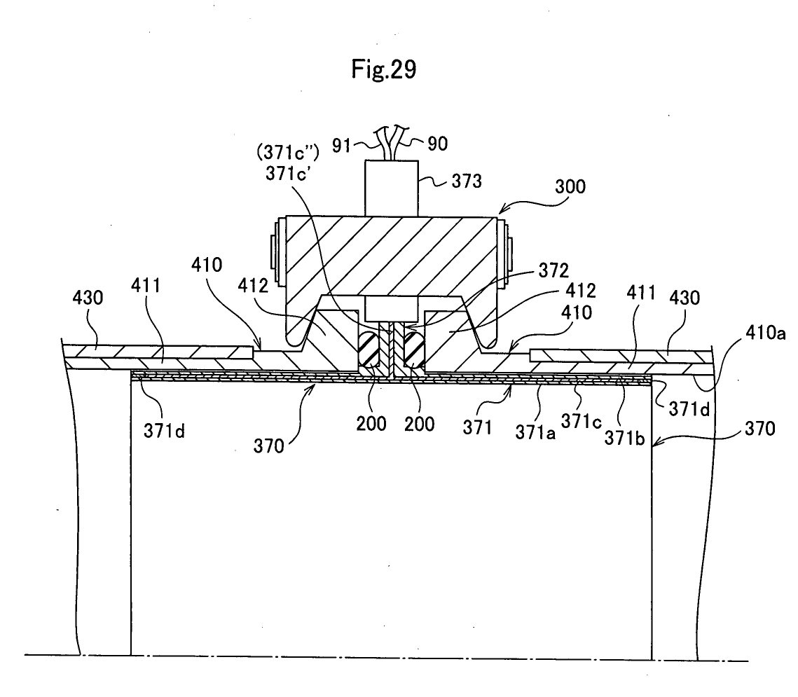

FIG. 29 through FIG. 31 show still another embodiment of the exhaust passage heating unit. In this embodiment, in a predetermined region apart from the flange portion 412 of the exhaust pipe 410, an external heater 430 is wound.

This exhaust passage heating unit 370 is formed of, as shown in FIG. 29 through FIG. 31, a cylindrical heating main body 371 disposed so as to be adjacent to and cover the inner wall face 410a across a predetermined region of the connection end between the exhaust pipes 410 and 410, an attaching portion 372 integrally formed into an annular and flange shape on the outer circumference of the heating main body 371, a connector 373 provided at the outer end of the attaching portion 372, and so on.

The heating main body 371 is formed of thin and cylindrical inner shell 371a and outer shell 371b as a pair of metal plates, a thin plate-shaped resistive heating element 371c sandwiched and covered between the shells 371a and 371b, a spacer 371d that joins the edges of the shells 371a and 371b and seals up the resistive heating element 371c, and so on.

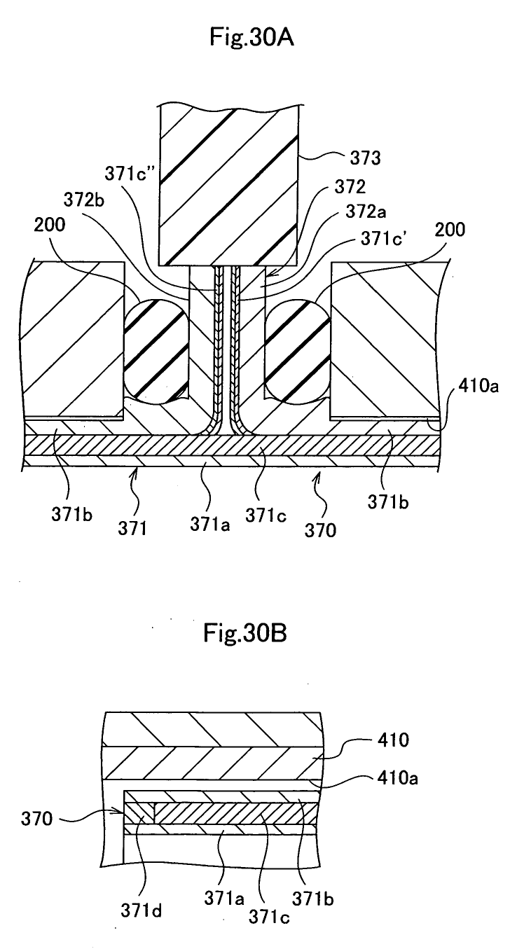

The spacer 371d is provided, as shown in FIG. 29 and FIG. 30B, at both edges to be exposed to the processing gas in the edges of the shells 371a and 371b to completely prevent the resistive heating element 371c from being exposed to the processing gas or the like.

The attaching portion 372 is formed of flanges 372a and 372b joined to the outer shell 371b as shown in FIG. 30A, and between the flanges 372a and 372b, a conducting lead 371c connected to the resistive heating element 371c and a lead 371c″ of a thermocouple as a temperature sensor for measuring the temperature of the resistive heating element 371c are sandwiched and drawn to the connector 373. Namely, the flanges 372a and 372b are not completely sealed up but are opened to the outside. At the connector 373, as shown in FIG. 29, a power supply cable 90 is connected to the lead 371c′ and a cable 91 to be connected to the measuring instrument is connected to the lead 71c″.

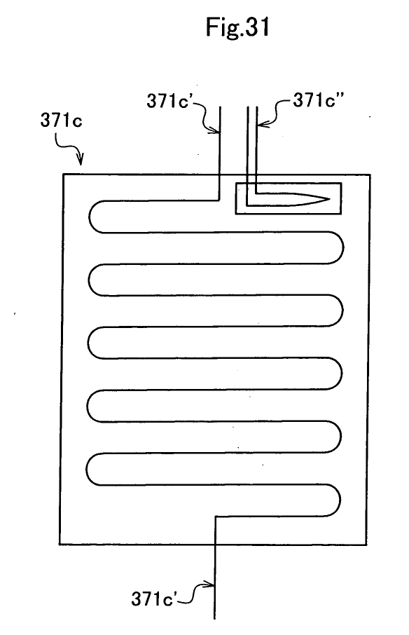

As the inner shell 371a, the outer shell 371b, and the flanges 372a and 372b, the same materials as those in the aforementioned chamber heating unit 50 are applied, and as the resistive heating element 371c, its form is shaped as shown in FIG. 31, and as its construction, the same as that in the aforementioned chamber heating unit 50 is applied. Herein, the construction in that the resistive heating element 371c is arranged in close contact with the shells 371a and 371b inside the shells 371a and 371b is shown, however, it is also allowed that the resistive heating element is spaced from the outer shell 371a.

As shown in FIG. 29, the heating main body 371 is inserted into the exhaust pipe 410 so that a slight space is left between the outer shell 371b and the inner wall face 410a, and the attaching portion 372 is sandwiched by the flange portions 412 while the O-rings 200 are attached, and is fastened by a clamp mechanism 300, whereby the exhaust passage heating unit 370 is completely attached, and the exhaust passage is insulated from the outside and is vacuum sealed. Similarly to the description provided above, the attaching and detaching operations can be easily performed, and the heating efficiency increases.

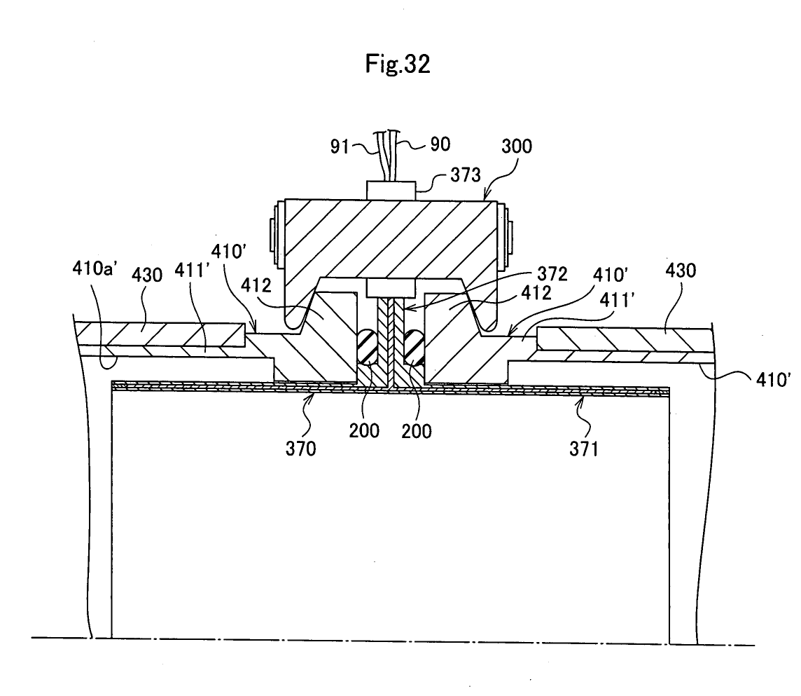

FIG. 32 shows an embodiment in which the exhaust passage heating unit 370 is attached to another exhaust pipe 410′. Namely, according to the embodiment, in the state in that the exhaust passage heating unit 370 is inserted into the cylindrical portion 411′ of the exhaust pipe 410′, the space left between the outer shell 371b and the inner wall face 410a′ becomes larger than in the above-described embodiment. In this case, the attaching and detaching operations are also easily performed and the heating efficiency increases similarly to the description provided above.

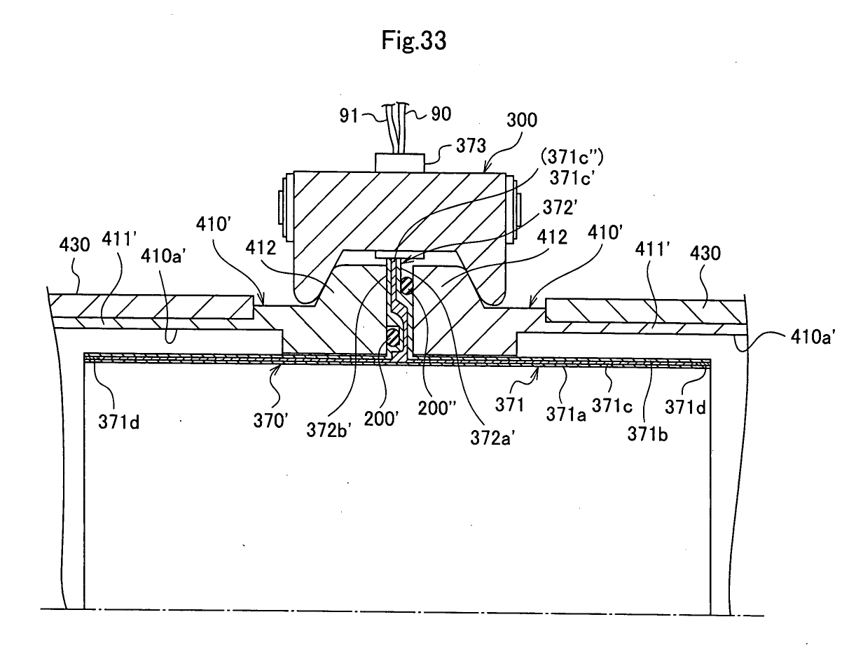

FIG. 33 shows an alteration of the attaching portion 372 of the exhaust passage heating unit 370. Namely, in this exhaust passage heating unit 370′, as shown in FIG. 33, the width of the attaching portion 372′ is narrowed, the flanges 372a′ and 372b′ are changed in thickness and bent, and O-rings 200′ and O-rings 200″ are disposed at radial inner and outer sides.

Thereby, the flange portions 412 and 412 of the exhaust pipe 410′ can be joined closer to each other. Even in this case, the attaching and detaching operations are also easily performed and the heating efficiency increases similarly to the description provided above.

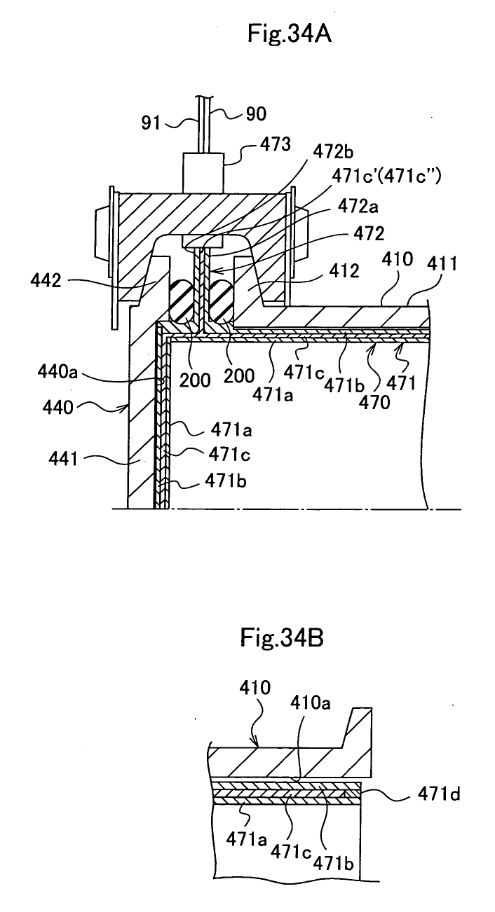

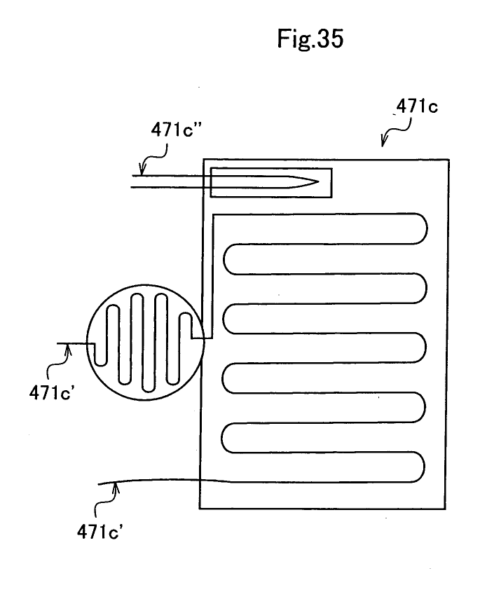

FIG. 34A, FIG. 34B, and FIG. 35 show an embodiment of an exhaust passage heating unit to be employed in a construction in which the connection end of the exhaust pipe 410 is closed by a cover 440. The cover 440 is formed of a disk-shaped closing part 441, a flange portion 442 disposed opposite the flange portion 412 at the outer circumference of the closing portion 441, and so on.

This exhaust passage heating unit 470 is formed of, as shown in FIG. 34A and FIG. 34B, a bottomed cylindrical heating main body 471 disposed so as to be adjacent to and cover the inner wall faces 410a and 440a of the exhaust pipe 410 and the cover 440, an attaching portion 472 integrally formed into an annular and flange shape at the outer circumference of the heating main body 471, a connector 473 provided at an outer end of the attaching portion 472, and so on.

The heating main body 471 is formed of thin and bottomed cylindrical inner shell 471a and outer shell 471b as a pair of metal plates, a thin plate-shaped resistive heating element 471c sandwiched and covered between the shells 471a and 471b, a spacer 471d that joins the edges of the shells 471a and 471b and seals up the resistive heating element 471c, and so on.

The spacer 471d is provided at both edges to be exposed to the processing gas in the edge portions of the shells 471a and 471b to completely prevent the resistive heating element 471c from being exposed from the processing gas or the like.

The attaching portion 472 is formed of, as shown in FIG. 34A, flanges 472a and 472b joined to the outer shell 471b, and between the flanges 472a and 472b, a conducting lead 471c connected to the resistive heating element 471c and a lead 471c″ of a thermocouple as a temperature sensor for measuring the temperature of the resistive heating element 471 care sandwiched and drawn to the connector 473. Namely, the flanges 472a and 472b are not completely sealed up but are opened to the outside. At the connector 473, as shown in FIG. 34A, a power supply cable 90 is connected to the lead 471c′, and a cable 91 to be connected to the measuring instrument is connected to the lead 471c″.

As the inner shell 471a, the outer shell 471b, and the flanges 472a and 472b, the same materials as those in the aforementioned chamber heating unit 50 are applied, and as the resistive heating element 471c, its form is shaped as shown in FIG. 35, and as its construction, the same construction as in the aforementioned chamber heating unit 50 is applied.

As shown in FIG. 34A and FIG. 34B, the heating main body 471 is inserted into the exhaust pipe 470 so that a slight space is left between the outer shell 471b and the inner wall face 410a, and in a state in that the O-rings 200 are attached, the cover 440 is joined so that a similar space is also left between the outer shell 471b and the inner wall face 440a, and the attaching portion 472 is sandwiched by the flange portions 412 and 442 and is fastened by the clamp mechanism 300, whereby the exhaust passage heating unit 470 is completely attached, and the exhaust passage is insulated from the outside and is vacuum sealed. Similarly to the description provided above, the attaching and detaching operations are easily performed and the heating efficiency increases.

In the above-mentioned embodiments, a sheet-like heating unit is shown that covers the inner wall faces 11a, 11b, 12a, and 13a of the processing chamber 11, the transferring passage 12, and the exhaust passage 13 and the inner wall faces 410a, 420a, 410a′, and 440a of the exhaust pipes 410, 420, and 410′ of a CVD device from the inner side. However, the heating unit is not limited thereto, and a sheet-like heating unit that covers the inner wall face of a supply passage for supplying a processing gas or the like can also be employed.

The above-mentioned embodiments show the case where the heating units 50, 60, 70, and 80 that heat all the processing chamber 11, the transferring passage 12, and the exhaust passage 13 in the CVD device are employed, however, it is also allowed that any one of the heating units is employed.

In the above-mentioned embodiments, a CVD device is shown as a semiconductor manufacturing device to which the heating unit of the present invention is applied, however, the heating unit is also applicable to an etching device or other processing devices.

According to the semiconductor manufacturing device and the heating unit thereof constructed as described above, improvement in yield of wafers to be treated, an increase in operating time, and reduction in power consumption by improvement in energy efficiency are realized by preventing or minimizing adhesion of by-products to the inner wall faces of the passages and processing chamber to be exposed to a processing gas or the like.

### INDUSTRIAL APPLICABILITY

As described above, as well as being applicable to a semiconductor manufacturing device such as a CVD device, an etching device or the like, the heating unit of the present invention can be used for other devices as long as the devices require direct heating of inner wall faces that demarcate passages or spaces from the inner side.

What is claimed is:

1. A semiconductor manufacturing device comprising:
a processing chamber;
a supply passage that supplies a processing gas to an inside of the processing chamber;
a transferring passage through which a wafer is put in and taken out of the processing chamber;
an exhaust passage through which the processing gas inside the processing chamber is exhausted; and
a sheet-like heating unit that in order to heat an inner wall face of at least one of the supply passage, the transferring passage, the processing chamber, and the exhaust passage, sandwiches and covers a thin plate-shaped resistive heating element by a pair of metal plates and covers the inner wall face from an inner side.

2. The semiconductor manufacturing device as set forth in claim 1, wherein
the heating unit includes a heating main body to be disposed adjacent to the inner wall face, an attaching portion formed into a flange shape or to extend integrally with the heating main body, and a connector that is provided at the attaching portion to draw out a wire for conducting electricity to the resistive heating element and a wire of a temperature sensor that detects a temperature of the resistive heating element.

3. The semiconductor manufacturing device as set forth in claim 2, wherein
a piping defining the exhaust passage is formed of a plurality of pipes that are formed to be attachable and detachable and joined to each other,
the plurality of pipes have sword guard-shaped flange portions that project radially outward and face each other, at connection ends, and
the attaching portion of the heating unit is sandwiched by the flange portions via a sealing member.

4. The semiconductor manufacturing device as set forth in claim 3, further comprising a clamp mechanism for joining the flange portions of the plurality of pipes, wherein
the clamp mechanism has a plurality of clamp blocks having grooves with roughly V-shaped sections to receive the flange portions so as to press the flange portions closer to each other, a plurality of link plates that link the plurality of clamp blocks, and a fastening member that fasten the two adjacent clamp blocks.

5. The semiconductor manufacturing device as set forth in claim 4, wherein
the plurality of link plates include a plurality of first link plates that link one side portions of the clamp blocks to each other and a plurality of second link plates that link the other side portions of the clamp blocks to each other, and
at least one link plate of the first link plates and the second link plates is formed so as to be latched on and released from the clamp block.

6. A heating unit of a semiconductor manufacturing device which heats an inner wall face of any of a processing chamber, a transferring passage through which a wafer is put in and taken out of the processing chamber, and an exhaust passage through which a processing gas inside the processing chamber is exhausted, comprising:
a thin plate-shaped resistive heating element; and
a pair of metal plates that are formed to sandwich and cover the resistive heating element, cover like a sheet the inner wall face from an inner side, and define the processing chamber or the passages.

7. The heating unit of a semiconductor manufacturing device as set forth in claim 6, wherein
the heating unit includes a heating main body that is disposed adjacent to the inner wall face, an attaching portion formed into a flange shape or to extend integrally with the heating main body, and a connector that is provided at the attaching portion so as to draw out a wire for conducting electricity to the resistive heating element and a wire of a temperature sensor that detects a temperature of the resistive heating element.

8. The heating unit of a semiconductor manufacturing device as set forth in claim 7, wherein
the heating unit includes a chamber heating unit that is disposed adjacent to the inner wall face of the processing chamber, and
the chamber heating unit includes a cylindrical heating main body to be disposed adjacent to a side wall face of the processing chamber and an attaching portion provided in a flange shape at an end of the heating main body, and a disk-shaped heating main body to be disposed to face a bottom wall face of the processing chamber and an attaching portion provided to extend on a lower face of the heating main body.

9. The heating unit of a semiconductor manufacturing device as set forth in claim 7, wherein
the heating unit includes a chamber heating unit to be disposed adjacent to an inner wall face of the processing chamber, and
the chamber heating unit includes a cylindrical heating main body having a bottom wall and an attaching portion provided in a flange shape at an opening end of the heating main body.

10. The heating unit of a semiconductor manufacturing device as set forth in claim 7, wherein
the heating unit includes a transferring passage heating unit that is disposed adjacent to an inner wall face of the transferring passage, and
the transferring passage heating unit includes a cylindrical heating main body having a roughly rectangular section and an attaching portion provided in a flange shape on the heating main body.

11. The heating unit of a semiconductor manufacturing device as set forth in claim 7, wherein
the heating unit includes an exhaust passage heating unit to be disposed adjacent to an inner wall face of the exhaust passage, and
the exhaust passage heating unit includes a cylindrical heating main body and an attaching portion provided in a flange shape on the heating main body.

12. The heating unit of a semiconductor manufacturing device as set forth in claim 7, wherein
the heating unit includes an exhaust passage heating unit to be disposed adjacent to an inner wall face of a curved exhaust passage,
the exhaust passage heating unit includes a curved cylindrical heating main body and an attaching portion provided in a flange shape on the heating main body, and
the heating main body is formed so that a heating value becomes higher in an outside region than in an inside region of the curved exhaust passage.

13. The heating unit of a semiconductor manufacturing device as set forth in claim 7, wherein
the heating unit is disposed by leaving a space for insulating heat between the heating unit and the inner wall face.
